(19) United States
(12) Patent Application Publication
(10) Pub. No.: US 2006/0250534 A1
(43) Pub. Date: Nov. 9, 2006

(54) Thin planar switches and their applications

(75) Inventors: Tuvia D. Kutscher, Shoham (IL); Doron Marco, Tel Aviv (IL); Gadi Turliuc, Raanana (IL); Tovit Goren, Rehovot (IL); Amir Eilat, Tel Aviv (IL)

Correspondence Address: Mr. Ronen Lin;Citala Ltd., 3 Habarzei Street, Ramat Hachayal, Tel-Aviv, IL, 69710, US

(73) Assignee: Citala Ltd., Tel Aviv (IL)

(21) Appl. No.: 10/745,287

(22) Filed: Dec. 22, 2003

Related U.S. Application Data
(63) Continuation of application No. PCT/IL02/00496.

(30) Foreign Application Priority Data
Jun. 20, 2001 (IL) 143887
Aug. 15, 2001 (IL) 144922
Aug. 15, 2001 (IL) 144923
Oct. 7, 2001 (IL) 145825
Oct. 16, 2001 (IL) 145966
Oct. 16, 2001 (IL) 145967

(51) Int. Cl. G02F 1/136

(52) U.S. Cl. 349/41

(57) ABSTRACT

A novel thin planar latching switch device, generally based on a layer of polymeric switching materials sandwiched between two electrical planar conductors operative as electrodes. The device behaves as a bi-stable switch. Furthermore, the switch device generally shows a memory effect. In the open state, when no voltage is applied to the electrodes, the switching material is effectively an insulator. When an electric field greater than a certain threshold level is applied to the switching material, the material becomes more conductive, and the device thus essentially becomes a closed switch. Applications of such switching devices are described for use in flat panel displays, generally based on liquid crystals, in high efficiency color displays, and in touch screens.

### FIELD OF THE INVENTION

The present invention relates to the field of latched planar solid state optical and electronic switching devices with a memory for the state to which they are switched, especially for use in planar switching applications, in flat panel displays, in high efficiency color displays, and in touch screen applications.

### BACKGROUND OF THE INVENTION

In various applications, it is desired to have a switching device with latching properties, such that when it is turned on, it remains latched in the closed state, until switched off again by means of a disenabling function. Such switches generally have bi-stable behavior, i.e. they have two preferentially favored switched conditions, open and closed, and have little tendency to be found between those two favored conditions. They also generally have non-ohmic behavior, i.e., they are nonlinear electronic devices, even before reaching their switching threshold. One of the earliest types of switching device with at least two conductive states has been reported in the article “Switching phenomena in titanium oxide thin films” by F. Argall, published in Solid State Electronics, Vol. 11, pp. 535-541, 1968, in which the titanium oxide films are grown by an anodizing process. References to other materials and switching devices, in which reversible switching between a high and low impedance state in dielectric materials are also given in this article. However, it would appear from the reported behavior that the switching effect is not always reproducible, and no details of any methods of application are given, nor are the applicants aware of any apparent commercial applications developed from these devices.

The bi-stable latching switches described in the prior art which have found commercial application are generally solid state semiconductor devices, such as four leg p-n-p-n devices, and, being multi-layered, are generally relatively complex and hence costly to manufacture and may have low yields. An example of such a prior art semiconductor bistable switch is shown in U.S. Pat. No. 3,986,177 to J. E. Picquendar et al., for a “Semiconductor store element and stores formed by matrices of such elements”. Another type of bistable switching device is described in U.S. Pat. No. 3,440,588 to C. F. Drake et al., for a “Glassy bi-stable electrical switching and memory device”. The device uses a glassy material, and its manufacture requires high temperatures, of the order of 1150 degrees Celsius, or a complex glow discharge method with a heated substrate. Neither of these methods would appear to be simple to perform, and even less so in a planar configuration.

Latching switches are used in a wide range of applications, ranging from power switching devices to non-volatile memory applications to flat panel displays, especially liquid crystal based displays. In the latter, arrays of thin film transistor (TFT) driven liquid crystal elements and storage capacitors are generally used to provide the latched switching capability required in large area displays. Such arrays are complex and expensive, thus making the cost of such active matrix displays comparatively high. Ferroelectric-based latching switches and liquid crystals are also used in the display industry, but their cost is also high.

Many commonly used flat panel displays are based on twisted nematic (TN) or super twisted nematic (STN) liquid crystal technologies. There are two main types of such displays, passive matrix liquid crystal displays and active matrix liquid crystal displays.

A passive liquid crystal display, as its name implies, does not require active electronic circuits, such as thin film transistors (TFT's) to drive it, and as such, is significantly less costly to produce than the active matrix TFT display. Consequently, passive displays are the preferred type for use in cost-sensitive applications such as in cellular telephones, hand held devices, personal device assistants (PDA's), and in other mass-produced, low cost appliances.

However, the performance of passive liquid crystal displays (LCD's) is noticeably inferior to that of active matrix LCD's in a number of areas. Table 1, below, adapted from a Web site operated by Loyola University, describing display device technology, presents a comparison of the major properties of the two types.

TABLE 1

| | Passive | Active matrix TFT |
|---|---|---|
| Contrast | 10-20 | 100+ |
| Viewing Angle | Limited | Wide |
| Gray Scale | 16 | 256 |
| Response Time | 100-200 msec | <50 msec |
| Multiplex ratio | 480 | >1000 |
| Manufacturability | Simple | Complex |
| Cost | Cheap-Moderate | High |

The primary reason for the inferior performance of passive LCD's in flat panel applications, where multiple lines need to be displayed, is a result of the method whereby their pixels are addressed by multiplexing. Information is applied to column electrodes one row at a time. The driving limitations of passive, root mean square (RMS) voltage responding, twisted nematic (TN) and super-twisted nematic (STN) LCD's can be described in terms of well-known formulae, developed by P. M. Alt and P. Pleshko in the article “Scanning Limitations of Liquid Crystal Displays” published in IEEE Transactions on Electronic Devices, Vol. ED-21, pp. 146 ff, 1974, herewith incorporated by reference in its entirety. Alt and Pleshko show that the number of lines that can be multiplexed depends on the steepness of the transfer characteristic of the liquid crystal material. Thus, when using TN LCD's, in order to multiplex 200 rows, the difference between the on and off voltages needs to be less than about 7%. In order to provide good contrast with such a small change of applied voltage requires a liquid crystal with a very steep characteristic. STN LCD's have the steepest characteristic of commonly used materials, and can be used with multiplexing ratios of up to about 480, but the contrast is generally limited to the order of 10 or 20:1, or even less. If not for the multiplexing problem, the obtainable contrast in passive LCD's could reach 100:1, depending on the liquid crystal technology used in the display. However, in order to achieve such contrast levels when multiplexing is used, an LCD material having a much steeper characteristic than those of currently available technologies, would be required, and such a material is currently unavailable, with the exception of Ferroelectric liquid crystal devices, which are expensive, lack gray scale and are difficult to fabricate. Reading such a passive display with more than about 400 rows using currently available materials is difficult, making such passive displays unsuitable for high resolution large screen devices, such as computer screens.

For this reason, passive type displays have been limited to simpler displays, such as hand held type displays, where the maximum number of rows driven is of the order of only 100-200, and the contrast can be compromised. In such applications, the high cost of using active matrix TFT displays in order to achieve higher resolution or contrast, is not warranted.

Another field of application in which planar switched devices are used is in the field of color displays. In currently available electronic color displays, whether based on cathode ray tube (CRT) technology, liquid crystal display (LCD) technology, or on other technology base, the color format displayed on the screen is generally presented by a standard method whereby each colored pixel is composed of three smaller subpixels, located side by side within the area of the composite larger pixel, each subpixel displaying a different color, such that a convex combination of the three colors with appropriate weighting, should provide the desired color of the composite larger pixel. The three colors generally chosen as a standard for this purpose, in order to produce all practically required colors, are Red, Green and Blue (RGB). The three colors may be implemented in the display in a number of different ways, including the use of independent light sources, and the use of color filters placed on each pixel. In the majority of applications, the color-filter approach is adopted, due to ease with which it can be implemented.

Unfortunately, this configuration is wasteful, both in terms of light utilization, and in terms of space utilization. For example, if the display pixel is to show a green color, only the green part of the pixel is illuminated and the red and blue remain dark. Thus, only 33% of the total pixel area is used. This has a two-fold outcome:
(i) The maximal resolution is lower by 66%, compared with the resolution attainable with a monochrome monitor, since the area of the combination of the three RGB sub-pixels is three times larger than that of a single pixel.
(ii) The light efficiency is lower by 66%, compared with the efficiency attainable with a monochrome monitor, meaning that the power consumption is three times higher than required for monochrome pixel filling.

Another field of application in which planar switched devices are used is in the field of touch screens. A touch screen is a computer display-screen that is sensitive to touch, allowing a user to interact with a computer-based information system by touching pictures, symbols or words on the screen. Touch screens are used in many current computer-based information systems, especially those whose operation is, by their nature, very user-interface intensive, such as PDAs, automatic cash machines, information-kiosks, computer-based training devices, and computer systems for disabled users who have a difficulty in operating a mouse or keyboard. Touch-screen technology can also be used as an alternative user-interface with applications such as Web browsers, that usually require a mouse. Furthermore, some applications are designed specifically for touch-screen technologies, often having larger icons and links than of the typical PC application. Despite being so common, the cost of these touch-sensitive devices has remained high in comparison to conventional keyboard interface equivalents.

Monitors are available with built-in touch screen technology, or alternatively, touch-screen kits can be provided separately for mounting on the front of conventional monitors. Four main types of touch-screen technologies are currently available—resistive, capacitive, infra-red and surface acoustic wave (SAW) based.

A resistive touch-screen typically uses a display overlay consisting of separate layers, each with a conductive coating on its inner surface. The conductive inner-layers are separated by special separator dots, evenly distributed across the active area. Finger pressure causes internal electrical contact at the point of touch, supplying the touch-screen controller with vertical and horizontally defined analog voltages, whose position can be digitized for input as the user interface.

Resistive touch screens use with CRT's are generally curved to match the curved CRT screen profile. This minimizes parallax. The nature of the material used for such curved applications limits the light throughput. Two options are generally available—clear polished or antiglare. The polished option offers clarity but includes some glare effects. The antiglare option minimizes glare, but results in a slightly diffuse image light throughput. As a consequence, such touch screens display either more glare or more light diffusion than would be associated with an equivalent non-touch screen display. Despite the tradeoffs, the resistive touch screen technology is currently probably the most commonly used type, possibly because it can be operated while wearing gloves, unlike the probably second most common type, based on capacitive technology, to be described below.

There also exist resistive touch-screen materials for use in flat-panel touch screens. Such materials are different from those used in curved screen CRT's, and demonstrate better optical clarity, even with a reasonable level of antiglare properties. Because of this, the resistive touch-screen technology is far more common for flat panel applications than for curved screen CRT applications.

A capacitive touch-screen typically includes a glass overlay coated with capacitive material which acts as a charge storing layer. Oscillator circuits located at the corners of the glass overlay measure the change in capacitance of the layer because of the finger of a person touching the overlay. This change in capacity causes each oscillator to vary its frequency of oscillation according to where the overlay is touched. A touch-screen controller measures these frequency changes, and thereby determines the coordinates of the point of contact.

Because the capacitive coating is generally at least as hard as the glass it is applied to, such capacitive touch screens are very resistant to scratches from sharp objects and can even resist spark damage. However, because of the nature of its operation, a capacitive touch-screen cannot generally be activated while wearing most types of gloves, which are non-conductive.

An infrared touch-screen incorporates a bezel of light emitting-diodes (LED's) and diametrically opposing phototransistor detectors surrounding the face of the display. The controller circuits direct a sequence of pulses to the LED's, scanning the screen with an invisible lattice of infrared light beams just in front of the surface. The controller circuitry is able to detect where the light beams become obstructed by any solid object, such as the user's finger, and inputs this location to the system. The disadvantage of infra-red touch screens is that the bezel system that houses the transmitters and detectors can impose design constraints on operator interface products.

A SAW touch-screen uses a solid glass display overlay for the touch sensor. Two ultrasonic surface-acoustic waves are transmitted across the surface of the glass sensor, one for vertical detection and one for horizontal detection. Each wave is spread across the screen by bouncing off reflector arrays along the edges of the overlay. Two receivers detect the waves, one for each axis. Since the velocity of the acoustic wave through glass is known and the size of the overlay is fixed, the arrival time of the waves at the respective receivers is known. When the user touches the glass surface, the water content of the user's finger in contact with the glass surface absorbs some of the ultrasonic energy, thus damping the acoustic wave. The controller circuitry measures the point in time at which the received amplitude of the two acoustic waves declines, thus determining the coordinates of the point of contact.

In addition to the X and Y coordinates, SAW technology can also provide Z axis (depth) information. The harder the user presses against the screen, the better the coupling of the acoustic wave to the finger, the greater the energy the finger will absorb, and the greater the dip in signal strength. The signal strength is then measured by the controller to provide Z-axis information.

Each of the above mentioned technologies has its advantages and its disadvantages, as known to those familiar with the art. Besides the specific disadvantages mentioned above, and those known generally, which are specific to one or another of the touch screen technologies, all of the technologies have two common disadvantages:
(i) They all require the use of an additional screen, and of special controllers and drivers for the touch screen panel, thereby increasing the cost of the touch-screen display.
(ii) These additional screens are placed in front of the display, thus lowering its light efficiency.

In the light of the above-described disadvantages and limitations of currently available planar latching switches and their uses in practical applications, there therefore exists a serious need for a layered latching switch, of simple construction and low cost, yet capable of being constructed with large surface areas.

There also exists a serious need for a flat panel display technology, which would have the construction simplicity, and hence low cost of a passive matrix LCD, and yet the resolution and contrast typical of the more expensive active matrix TFT LCD.

There therefore also exists a serious need for a color display device, which will have a higher resolution and power efficiency than currently available color monitors, such that the resolution and efficiency should more closely approach that available from monochrome monitors.

There also exists an important need for a new type of touch screen, which will overcome many of the above-mentioned disadvantages of the prior art touch screens.

The disclosures of all publications mentioned in this specification, and the disclosures of all documents cited in such publications, are hereby incorporated by reference, each in its entirety.

### SUMMARY OF THE INVENTION

The present invention seeks to provide a new latched, solid state electronic bistable switching device, especially capable of being constructed in large surface area layers, such that it can be advantageously used in flat panel displays, in high efficiency color displays, in touch screens, or in other large area applications. For use in these applications, the device is preferably transparent to visible light. The electronic nature of the device is that it has a memory for the state to which it is switched, and has a low tendency to switch back until constrained to do so by the device re-setting conditions. The term planar used in this specification, and as claimed, is understood to include also slightly contoured surfaces, such as would be formed from flexible materials.

There is thus provided, in accordance with a preferred embodiment of the present invention, a device consisting of a layer of a switching material, sandwiched between two electrical conductors operative as electrodes. The device behaves as a bi-stable switch. In the open state, when no voltage is applied to the electrodes, the switching material is effectively an insulator, and the device behaves like a capacitor in parallel with parallel stray resistance, as expected from an insulating material sandwiched between two electrodes. When an electric field greater than a certain threshold level is applied to the switching material, the material becomes conductive, and the device thus essentially becomes a closed switch, with a comparatively low resistance. The field may be simply generated by applying a voltage to the two electrodes. Furthermore, on removal of the field, the switch remains in its closed state for a specific time, such that the switch is a latched, bi-stable switch. The applied field may be a DC field, or an AC field.

The switching device can preferably be provided as a planar layer, or if suitably constructed, may be contoured to match a curved surface, such as that of a CRT surface, or an even more curved surface. If constructed with flexible electrode substrates, the device can be curved to match almost any desired smooth object on which it is to be applied. Though the invention is generally described in this specification in terms of a flat planar configuration, and is also thus generally claimed, this probably being its most common mode of use, it is to be understood that the invention is not meant to be limited to planar switching devices, but is equally operable in curved surface configurations.

The layer of switching material may be sandwiched between the electrodes of the device according to any suitable method which provides a suitably smooth and uniform thickness layer. According to a first preferred method, the switching material is spread onto a first substrate on which are deposited one set of electrodes, and a second substrate with the second set of electrodes is brought into close contact with the first substrate, squeezing out any excess switching material to leave a thin layer. The thickness of this layer, and its uniformity are determined by means of spacers of known thickness located between the substrates.

According to a second preferred method, the switching material is spin coated onto one of the substrates by standard methods, known in the art. The spun coatings are generally much thinner than the spread and squeezed layers.

In accordance with another preferred embodiment of the present invention, the switching material may consist of an insulating material in which is dispersed a small percentage of a conductive material. Such materials are used in switch layers formed by spreading and squeezing. A convenient preferred configuration of the switching material may be obtained in the form of a small quantity of a finely divided metal suspension in an insulating epoxy. This configuration can preferably be made by mixing the metal in the form of a colloidal suspension of nano-particles or micro-particles with the epoxy. The epoxy mixture does not necessarily have to be cured, and the device operates satisfactorily whether the epoxy is cured in the usual manner by the addition of the hardening catalyst, or is uncured, by the omission of any hardener addition. The switching characteristics are, however, somewhat different in the two cases. Other preferable insulating materials include some polymers, adhesives such as contact adhesive, and a range of other viscous liquids and solids, including gels and oils. The term insulating material is used and claimed throughout this specification in a comparative sense, since the requirement is that its resistivity be considerably higher than that of the conductive state, whether or not it would be called an insulator in absolute terms.

The percentages of conductive material preferably used are from the order of 0.005% to 20%, though concentrations outside of this range may also provide the switching material with its special properties. According to further preferred embodiments of the present invention, commercial grade organic solvents, such as acetone or PMA (Propylene Glycol Methyl Ether Acetate) can also be used as a switching material, without the addition of any conductive material. These commercial grade solvents, however, generally contain small concentrations of metallic ions, and it is possible that it is these ions which may be operative as the conducting elements in these embodiments of the present invention. However, this suggested mechanism is only a hypothesis, and it should be emphasized that these embodiments of the invention are operative irrespective of the actual physical processes operating in the device. Pure insulators without any significant levels of conductive material, such as clean oil, generally cannot however be used in such thick spread layers.

Similarly, though the use of an epoxy carrier is a particularly convenient method of implementing the switching material, alternative and preferable methods of producing the material may also include the dispersion of the conductive suspension in a thermosetting or other plastic insulating material, or in other suitable organic or inorganic insulators.

The switching materials containing dispersed conductive materials are generally preferably used in the embodiments of the switches where the switching layer is spread and squeezed, and is thus comparatively thick. The switching materials without any conductive material additive are generally used in the preferred embodiments of the switches where the switching layer is spun coated, and is thus comparatively thin. It would appear that the mechanism operative in the switching materials without any conductive additives is such that the thickness used much be much thinner than those with conductive additives.

The open and closed resistance and the self capacitance of the device, which together determine the transient response of the switch, can be selected by controlling the parameters of the switching material. These parameters include the nature of the conducting material used, the nature of the insulating material used, the concentration of the conducting material in the insulating material matrix, and the thickness of the switching material layer. Furthermore, the level of switching voltage applied above the threshold value, also influences the time taken for the switch to close, and its resistance once closed.

After the device has been turned to its closed state, it remains in that state even when the field applied across it is reduced below the threshold level, or even to zero. Even the application of a moderate reverse field does not generally open the switch, and the switch thus has a robust level of latching. Some embodiments of the switch remains closed for comparatively long periods of time, even for a number of seconds, depending on the parameters of the device and the ambient conditions. Some preferred materials allow the switch to remain closed for the order of hours or even days.

The various embodiments of latching switches according to the present invention can be divided into a number of distinct types according to the memory duration of the switching transition in the switching material. These types are conveniently termed full-memory (FM) switches, partial memory (PM) switches, sustainable memory (SM) switches and zero memory (ZM) switches. For the FM devices, after application of a switching voltage to alter the state of the switch to a high conductivity state, the switch typically retains this high conductivity state, unless actively opened, for a long period, preferably of minutes or even several hours. For the PM devices, the conductivity memory is maintained for a period ranging between the order of hundreds of microseconds to milliseconds. More importantly, PM switches have a well defined memory range. They have a well defined upper time limit, beyond which time the material resets itself to its original state if no voltage is applied, and a well defined lower limit during which the material retains its current state, if no voltage is applied across it. For the SM devices, the closed state is maintained only if a sustaining voltage is applied to the switch, under which conditions, it can maintain its conductive state for very long periods. generally the SM switches are only committed to remaining closed while a sustaining voltage is present, they are not committed to rapid reset upon voltage removal. For the ZM devices, the switch reverts to its normal high resistance mode almost immediately after the switching voltage is removed, typically after a time period of between a few nanoseconds and 100 nanoseconds.

Besides the applications of the latched planar switching devices described above as switches, according to further preferred embodiments of the present invention, they may be used as memory elements, with the same delineation into types according to the time during which the memory can holds its information. For such applications, the FM switch configuration, being non-volatile, seems to be the most appropriate.

A preferred method of opening any of the above-mentioned switches again is by the application of physical stress to the device, either in the form of pressure, or in the form of bending, or by the application of heat. Preferred methods of switching off the device thus include the application of mechanical shock, stress or vibration. One preferred method of applying these in a controlled manner is by the use of a piezoelectric chip or layer attached to the device to introduce a level of stress into the switching material. Alternatively and preferably, the piezoelectric material can be mixed into the switching material. According to yet another preferred embodiment of the present invention, the addition of an elastomer to the switching material facilitates its reversal to the open state much more rapidly. According to yet more preferred embodiments, the use of a viscous or a gel-like insulating matrix material, also facilitates the switch reversal to the open state.

The switch, according to more embodiments of the present invention, may be sensitive to the pressure applied to it, the greater the pressure applied, the greater being the voltage required to close it. Consequently, according to another preferred embodiment of the present invention, the device can be used as a pressure sensor.

Once the switch has been opened, the threshold voltage required to close it again depends on the elapsed time since opening. Generally, the longer the elapsed time, the higher the voltage required. When the switch is closed a very short time after being opened, the voltage required is only a fraction of that required to close it when it has been at its equilibrium open state, typically as little as 10% of the normal threshold voltage under some conditions.

In addition to its electrical switching properties, the device, according to further preferred embodiments of the present invention, also has optical transmissive properties, parallel in some respects, to its electrical switching properties. Thus, for the preferred embodiments with the higher levels of conducting material concentration, where there is a noticeable level of opacity in the unexcited, open switch, the operation of closing the switch causes the optical transmission to increase significantly in comparison with its open state. Likewise, even when the exciting voltage is removed, the latched closed optical switch remains transparent for a specific time interval, in a comparable manner to its electrical behavior.

There are often differences in behavior of optical switches, in comparison with their electrical equivalents. In many combinations of materials, the optical switch begins to close at a lower voltage than the equivalent electrical properties. Furthermore, the transition from opacity to transparency, in many combinations of switch, takes place more gradually in the optical version, than in the electrical version, the transmissivity of the switch being a smoother function of applied voltage. This properly may be advantageously applied in some preferred embodiments of the present invention whereby optical switches are used in display panels.

The fact that the device structure is planar enables the production of the device in the form of large sheets. This form of implementation of the present invention enables the application of the latching switch in a number of useful applications, particularly in novel flat panel displays based on liquid crystal technology, in a new type of touch screen for use with flat panel displays or independently, and in the construction of novel types of color displays. Further applications are described in co-pending US Provisional Applications:
1. U.S. Application No.: 60/330,228 by Tuvia Kutscher, entitled “A Novel Numeral Display Panel”, submitted on Oct. 18, 2001 and
2. U.S. Application No.: 60/330,485 by Tuvia Kutscher, entitled “Optical Interconnects”, submitted on Oct. 23rd 2001,
   both of which are hereby incorporated by reference in their entirety.

In accordance with yet more preferred embodiments of the present invention, there is provided a switching device including a pair of preferably planar electrodes for applying a switching voltage, and a switching material disposed between the electrodes, the switching material including a mixture of a conductive material dispersed in an insulating material. According to this preferred embodiment of the present invention, the switching material may be such that the switching device closes only when the voltage is greater than a predefined threshold voltage. Furthermore, the switching material may be such that the switching device is bi-stable, or latched.

Additionally and preferably, the insulating material may be an epoxy resin, cured or uncured, or a polymer. The conductive material may preferably be a metal, which could preferably include be silver, iron, gold, copper or zinc. The concentration of the conductive material may preferably be in the range of 0.005% to 20%. In accordance with yet another preferred embodiment of the present invention, the insulating material may an organic solvent and the conductive material may be the metallic impurities present in the solvent.

In accordance with still another preferred embodiment of the present invention, there is provided a switching device as described above, and also including a piezoelectric component operative to open the switch when closed. The piezoelectric component may be dispersed in the switching material. Alternatively and preferably, the switching material also includes an elastomeric component.

There is further provided in accordance with still another preferred embodiment of the present invention, a switching device as described above, and wherein the electrodes comprise a transparent conductive layer coated on a thin insulating sheet. The transparent conductive layer may preferably be indium tin oxide.

In accordance with a further preferred embodiment of the present invention, there is also provided an optical switching device including a pair of generally transparent planar electrodes for applying a voltage, and a layer of generally transparent switching material disposed between the electrodes, the switching material including a mixture of a conductive material dispersed in an insulating material.

In accordance with yet a further preferred embodiment of the present invention, the switching material of the optical switching device is such that the optical transmission is a function of the applied voltage. Furthermore, the switching material may be such that the switching device is bi-stable, or latched.

Additionally and preferably, the insulating material of the optical switching device may be an epoxy resin, cured or uncured, or a polymer. The conductive material may preferably be a metal, which could preferably include be silver, iron, gold, copper or zinc. The concentration of the conductive material may preferably be in the range of 0.005% to 20%. In accordance with yet another preferred embodiment of the present invention, the insulating material may an organic solvent and the conductive material may be the metallic impurities present in the solvent.

In accordance with still another preferred embodiment of the present invention, there is provided a switching device as described above, and also including a piezoelectric component operative to open the switch when closed. The piezoelectric component may be dispersed in the switching material. Alternatively and preferably, the switching material also includes an elastomeric component.

There is further provided in accordance with still another preferred embodiment of the present invention, a switching device as described above, and wherein the electrodes comprise a transparent conductive layer coated on a thin insulating sheet. The transparent conductive layer may preferably be indium tin oxide.

There is even further provided in accordance with a preferred embodiment of the present invention a switching material including an insulating base material, and a conductive material dispersed through the insulating base material, wherein the switching material changes its electrical conductivity in a latched manner when subjected to an applied electric field.

Furthermore, in accordance with yet another preferred embodiment of the present invention, there is provided a switching material including a transparent insulating base material, and a conductive material dispersed through the insulating base material, wherein the switching material changes its optical transmissivity in a latched manner when subjected to an applied electric field.

The present invention further seeks to provide a new flat panel display, wherein a transparent latching switch layer is incorporated into a display, either above or below the pixelated imaging layer of the display, and in electrical contact with that layer. This switch layer is preferably constructed of a layer of switching material, and a preferred location for the layer is sandwiched between one of the electrodes of the imaging layer, and the imaging layer itself. The switching layer is preferably of the latching type, such that when switched to the closed state, it maintains that closed state for a time substantially longer than the cycle time of the display device. Each pixelized area of the latching switch layer is switched by the field or current resulting from the voltage applied to the imaging pixel in contact with it and immediately above or below it. The pixelated imaging display is preferably based on liquid crystal technology, though it is to be understood that the present invention is operable when based on any other, functionally similar, display technology.

On application of a data signal to turn on a specific pixel, by means of the correctly selected column and row of the display array, the switch pixel in immediate contact with that specific display pixel is closed. The voltage required to close the switch pixel is dependent on the properties of the switching layer itself, and should be greater than what is termed the switching threshold voltage. Because of the latching properties of the switching layer, the switch pixel remains closed for a time much longer than the cycle time of the display. In order to maintain that pixel in the switched-on state for an indefinite length of time, an activation signal, with voltage greater than the switched-on voltage of the imaging display element, but less than the latching switch threshold voltage may need to be required. Thus, the entire image may preferably be first written by means of sequentially setting the pixels of the latched switching device in the open or closed state, and then an activation voltage applied to the imaging device in order to turn on all the pixels, whose respective switches are closed. The switches' state can then be held effectively indefinitely by the application of the activating voltage to every pixel in the whole of the array simultaneously. If the switching layer is of a type which remains latched closed indefinitely, then no such activating voltage is required for the switch, but only for turning on of the imaging device.

In these flat panel display applications, the properties of the latching switch are used to emulate the function of the thin film transistor (TFT) in an active matrix liquid crystal display. In such a display, a row of pixels is selected by applying the appropriate select voltage to the select line connecting the TFT gates for that row of pixels. When a row of pixels is selected, the desired voltage can be applied to each pixel via its data line. When a pixel is selected, it is necessary to apply a given voltage to that pixel alone and not to any non-selected pixels. Those non-selected pixels should be completely isolated from the voltages circulating through the array, necessary to drive the pixels which were selected, and it is the TFT which provides this isolation function. Ideally, the TFT active matrix can be considered as an array of ideal switches, having zero closed resistance, and infinite open resistance.

The use of a large planar latching switch layer according to the present invention, disposed between the liquid crystal layer and one of its drive electrodes, is able to fulfill the same function as the TFT, but in a passive type of LCD geometry, without the expense and complication of a TFT array and its driving circuitry. The planar latching switch is preferably transparent in order to fulfill its function in this embodiment. Though these embodiments have been described in terms of a liquid crystal display, it is to be understood that it is applicable also to any other type of pixelated display operated by means of the voltage applied across the pixels.

According to the preferred embodiments of the invention described above, the latched switching layers themselves are uniform continuous layers. They preferably attain their pixelated nature by virtue of the pixelated nature of the associated electrode structure, which operatively divides the switching layers into effectively pixelated areas corresponding to the pixels of the electrode array. It should be evident, though, to one skilled in the art, that the invention is equally operable using switching layers which are physically divided into pixels on a microscopic scale, each pixel preferably being controlled by its own electrodes. It is thus to be understood that the term pixelated, as used to describe the switching layers, and as claimed in this application, is meant to include both physically pixelated layers, and virtually or effectively pixelated layers by virtue of the pixelated nature of the associated electrode structure.

There is thus provided in accordance with a preferred embodiment of the present invention, an imaging display including an imaging layer divided into pixels, each of which is separately addressable by signals applied via the switching layer, and a latched switching device in electrical contact with the imaging layer, each area of the latched switching device being switchable to a closed position by the application of the signal applied to the pixel in contact with that area.

In accordance with yet further preferred embodiments of the present invention, there is also provided a display including a pixelated imaging layer, the pixels of the layer being separately addressable by applied signals, and a latched switching device in electrical contact with the imaging layer, each area of the latched switching device being switchable to a closed state by the application of the signal applied to the pixel proximate to the area. The imaging layer may preferably be a liquid crystal device.

In accordance with still another preferred embodiment of the present invention, the applied signals are provided by sets of orthogonal conductors disposed on either side of the imaging layer and the latched switching device. The pixels of the latched switching device may preferably be latched closed by the applied signals, and may be such as to maintain their electrical state after the applied signals have been removed.

In the display described above, the latched switching device may preferably include a layer of switching material, and this switching material could preferably include a mixture of a conductive material dispersed in an insulating material.

There is further provided in accordance with still more preferred embodiments of the present invention, a display as described above, and wherein the latched switching device is selected from a group consisting of organic switches, glassy-type bi-stable switches, semiconductor array bi-stable switches, low-band gap conjugated polymer switches, amorphous chalcogenide semiconductors, ZnSe—Ge heterostructures, amorphous silicon conducting polymers, a variety of binary and ternary oxides, ferroelectric heterostructures, MIM structures with oxides such as (Ba,Sr)TiO₃, SrZrO₃, SrTiO₃, Ca₂Nb₂O₇ and Ta₂O₅ doped with up to 0.2% of Cr or V as the insulator layer, and molecular switches.

In any of the displays described above, the impedance of the switching device may preferably be a variable function of the applied signals, such that the pixels of the imaging layer can be switched to various gray levels. Furthermore, the pixels may be real pixels, or may be formed at the intersections of the orthogonal conductors mentioned above.

In accordance with a further preferred embodiment of the present invention, there is also provided a method of displaying an image in a display device, including the steps of:
(a) providing an imaging layer divided into pixels, each of the pixels being separately addressable by an applied switching voltage,
(b) providing a latched switching device in electrical contact with the imaging layer,
(c) applying a switching voltage to a pixel of the imaging layer, the switching voltage being sufficient to close the switch in the area of the latched switching device in contact with the pixel,
(d) applying further switching voltages sequentially to other pixels of the imaging layer according to the image desired, and
(e) thereafter applying an activating voltage simultaneously to a plurality of pixels of the imaging layer, the activating voltage being sufficient to switch the pixels of the imaging layer to show the image desired.

In the above mentioned method, the switching voltages may preferably be applied by means of orthogonal conductors located on either side of the imaging layer and the latched switching device. The switching voltages may be DC voltages or AC voltages. Furthermore, the pixels may be real pixels, or virtual pixels, formed at the intersections of the orthogonal conductors.

There is further provided in accordance with still another preferred embodiment of the present invention, a system comprising a plurality of elements, each of the elements having at least two alternate operative conditions. The system operates by alternating the operative conditions of its elements. The system also contains a latched switching layer disposed in electrical contact with the plurality of elements, and the operative condition of any element is alternated by the application of a signal to the series combination of the element and the latched switching layer adjacent to the element and in serial electrical contact therewith.

The present invention also seeks to provide a new type of color display device, in which the generation of the color is performed by means of a subtractive color process, rather than the additive process used in prior art display devices.

In accordance with a first preferred embodiment of a color display according to the present invention, the latching optical switch of the present invention are utilized to construct new forms of color displays, based on a subtractive system of color generation, rather than the additive system used in current displays. According to this preferred embodiment, the screen is made up of three layers of pixelated latched optical switches, according to the present invention, arranged in tandem, one on top of the other. One of the layers has its conductive metallic dispersion colored cyan, the second, magenta, and the third yellow. These colors are those conventionally used in subtractive color printing or display processes, as is well known in the art. When no voltage is applied across a pixel in the first layer, the color of the pixel is that of the colored metal namely cyan. Application to the electrodes of that pixel of an increasing voltage, causes the pixel to change from its non-transparent cyan color to become virtually fully transparent, if the switching layer has been correctly constructed, and the materials correctly selected, without too high or low a concentration of metal. Likewise for the second layer, any pixel can be switched from a fully opaque magenta to virtually transparent, and likewise for the yellow, third layer. Since the layers are in series, the screen thus has the property that any pixel can be switched from virtually complete transparency to any combination of the cyan-magenta-yellow color combination, thus providing a reflective display which emulates the subtractive color printing process.

Though this novel color display panel embodiment has been described using the above described optical switching device as its operative element, it is to be understood that it is operable also with any other type of pixelated display material which can be transformed from transparent to any other color by means of the voltage applied across the pixels.

Such a display has a substantially greater resolution and light efficiency than most currently used color display technology, wherein each pixel is subdivided into three primary colored sub-pixels. In this prior art technology, the spatial resolution is only one third of that of the novel color display according to these embodiments of the present invention. Furthermore, the electrical efficiency may be only one third of that of the color displays of the present invention, since in the prior art sub-pixelated displays, the area covered by, for instance, a green sub-pixel is only one third that of a green pixel according to these described embodiments of the present invention.

There is thus provided in accordance with a preferred embodiment of the present invention, a color display, including three pixelated filters, each of a different color, stacked one on top of each other and in close contact to avoid parallax effects between them. The color density of each of the pixels in each of said filters is capable of being varied electrically from its maximum color density to essential transparency, by the application of suitable control voltages to each pixel. The colors of the three filters constitute a subtractive color set, which may preferably be cyan, magenta and yellow, as used in conventional subtractive color printing systems.

The color display described above can preferably be used either as a reflective display, by positioning a reflective surface behind the three pixelated filters opposite to the side from which the display is to be viewed. Alternatively and preferably, it can be used in a transmissive embodiment by illuminating it from the side distant from the viewer with a white light source.

According to another preferred embodiment of the present invention, the pixelated colored filters may be constructed using the latched planar optical switch array described hereinabove. The planar switch is constructed of a pair of generally transparent planar electrodes, each of which is preferably in the form of a set of parallel conductors, the conductors being aligned orthogonally, such that they define a set of pixels. These electrodes are used for applying the control voltages to each pixelated area of the switch. Between these electrodes is sandwiched a layer of switching material made of a mixture of a conductive material having the color of the filter in which it is installed, dispersed in an essentially transparent insulating material. The switching material is preferably such that the optical transmission of a pixel is continuously variable as a function of the voltage applied to that pixel, ranging from the full color density of the filter, down to essential transparency of the pixel.

According to the preferred embodiments described above, the filters themselves are uniform continuous layers. They attain their pixelated nature by virtue of the pixelated nature of the associated electrode structure, which operatively divides the filters into effectively pixelated areas corresponding to the pixels of the electrode array. These electrode arrays are preferably two arrays of conductors running in directions orthogonal to each other, defining the pixels at their cross-overs. It should be evident, though, to one skilled in the art, that the invention is equally operable using filters which are physically divided into pixels on a microscopic scale, each pixel preferably being controlled by its own electrodes. It is thus to be understood that the term pixelated, as used to describe the filters, and as claimed in this application, is meant to include both physically pixelated filter, and virtually or effectively pixelated filters, by virtue of the pixelated nature of the associated electrode structure.

There is further provided in accordance with another preferred embodiment of the present invention, a color display, including three pixelated filters of different colors disposed one on top of each other, the color density of each of the pixels in each of the filters being electrically variable from its maximum color density to essential transparency, wherein the colors of the three filters constitute a subtractive color set. The subtractive color set may preferably comprise the colors cyan, magenta and yellow.

In accordance with yet another preferred embodiment of the present invention, the color display described above may also include a reflective surface disposed behind the three pixelated filters at a location opposite to the side from which the display is adapted to be viewed.

Furthermore, each of the filters may either be effectively pixelated by means of generally transparent planar arrays of electrodes defining pixelated areas on the filters, or alternatively and preferably, each of the filters may be physically pixelated.

In accordance with still another preferred embodiment of the present invention, in the above mentioned color display, each of the pixelated filters preferably includes a pair of generally transparent planar arrays of electrodes for applying voltages, the arrays of electrodes defining pixelated areas on the filters, and a layer of material disposed between the electrodes, the material including a mixture of a conductive material having the color of the filter in which it is installed, dispersed in a generally transparent insulating material, such that the optical color density of the pixelated areas of the filters is varied by the applied voltages. The conductive material may be a finely divided metal, which could preferably be selected from a group consisting of silver, iron, gold, copper and zinc. Furthermore, the insulating material may be a polymer, or even preferably an epoxy resin. In accordance with a further preferred embodiments of the present invention, the conductive material may be colored by the association thereto of a dye, or by means of an organo-metallic complex. The pixelated planar electrodes may preferably be made of indium tin oxide.

There is also provided in accordance with yet a further preferred embodiment of the present invention, a method of generating colors electronically in a display panel, including the steps of:
(a) providing a set of three pixelated filters of colors constituting a subtractive color set, the transmission of the filters being electrically variable from maximum color density to essential transparency,
(b) aligning the filters one on top of each other, such that sets of corresponding pixels are linearly superposed,
(c) applying voltages to at least one set of superposed pixels, one pixel in each of the filters, and
(d) adjusting the color densities of the at least one set of superposed pixels by varying the voltages, such that light passing through the set of superposed pixels acquires a predetermined color by means of a subtractive color process.

In the above-mentioned method, each of the filters may be effectively pixelated by means of generally transparent pixelated planar arrays of electrodes defining pixelated areas on the filters, or alternatively, each of the filters may be physically pixelated.

In accordance with this method, the display panel preferably may have a resolution approximately three times better than a corresponding additive display, and an optical efficiency approximately three times better than a corresponding additive display.

Furthermore, in accordance with yet another preferred embodiment of the present invention, there is provided a method of improving the resolution of a display panel including three sets of pixelated filters of different colors, including the steps of selecting the colors to be a subtractive color set, disposing the filters one on top of the other, such that at least one set of corresponding pixels of each of the filters are superposed, and activating the set of superposed pixels in a subtractive mode.

There is further provided in accordance with still another preferred embodiment of the present invention a method of improving the optical efficiency of a display panel including three sets of pixelated filters of different colors, including the steps of selecting the colors to be a subtractive color set, disposing the filters one on top of the other, such that at least one set of corresponding pixels of each of the filters are superposed, and activating the set of superposed pixels in a subtractive mode.

The pressure sensitive properties of the above described latching switch device, whereby application of pressure is operative to open a switch element which is latched close, as described above, enables the devices of the present invention to be used, according to further preferred embodiments of the present invention, as a novel touch panel or touch screen. The touch panel can preferably be used like conventional touch panels, as a separate unit, mounted in front of the screen in conjunction with which it operates, but without any direct electrical association therewith. In such an embodiment, the touch panel is preferably constructed of a large latching switched panel, made up of a layer of switching material sandwiched between two thin transparent substrates. Each of the substrates has an array of transparent conductors deposited thereon, one in each orthogonal direction. The entire touch screen is held latched closed by application of an overall switching voltage. When the pressure of a touch opens one of the pixels of the touch screen, electronic circuitry which scans the entire panel row by row and column by column, by means of the two orthogonal arrays of conductors, reveals which pixel is open, and thus provides information about the location of the touch.

Alternatively and preferably, the touch panel can be incorporated into a display panel, by incorporating the switching layer into the display element screen structure, generally above the display element layer itself, such that the effects of the pressure of the touch interact directly with the operation of the display element pixels. The scanning circuitry then has to determine whether the series impedance of the touch panel pixel and its underlying display element pixel has changed. The display element layer can preferably be a liquid crystal element layer, as is commonly used in flat panel displays.

According to a further preferred touch panel embodiment of the present invention, the change in impedance of an element of the touch panel is operative to change the current flow through its underlying display element pixel, and thus to change the transmissive or reflective state of the pixel in accordance with whether the element has been touched or not. In this manner, an integrated interactive touch panel can be implemented. All of the above described embodiments are operable either with the commonly used liquid crystal types of display, or with any other type of pixelated display operated by means of the voltage applied across its pixelated elements.

In addition to the latched planar switches described hereinabove, there also exist further types of latched planar switches, which operate in the reverse direction, i.e. when open, the application of pressure causes them to close. It is to be understood that, although preferred embodiments are described in this application using switches which are opened by pressure, equivalent touch panels can be constructed, according to further preferred embodiments of the present invention, wherein switches which are closed by the application of pressure are utilized.

There is thus also provided in accordance with a preferred embodiment of the present invention, a touch panel comprising a first planar electrode having a first array of conductors, a second planar electrode having a second array of conductors oriented at an angle to the first array of conductors, and a pressure-sensitive, planar latching switching layer disposed between the electrodes. The first array of conductors and the second array of conductors preferably define at their crossing points, a set of pixels for the touch panel. The angle of orientation may preferably be such that the first and second arrays of conductors are essentially orthogonal.

In the touch panels described above, the switching layer may be such that the action of pressure on an area of the layer is to open closed switch regions within the area, or according to alternate embodiments, to close open switch regions within the area.

There is further provided in accordance with yet another preferred embodiment of the present invention, a touch panel as described above, wherein the position of the pressure is determined by measurement of the impedance between at least one of the conductors of the first array and at least one of the conductors of the second array. Alternatively and preferably, the position of the pressure may be determined by sequential electronic scanning of the first array of conductors and the second array of conductors to detect impedance changes between any pair of conductors, one from the first array of conductors and one from the second array of conductors.

Any of the above-described touch panels may be overlaid on a flat panel display, such that the touch panel is operative with the display.

In accordance with still another preferred embodiment of the present invention, there is provided a touch screen comprising a first planar electrode having a first array of conductors, a second planar electrode having a second array of conductors oriented at an angle to the first array of conductors, a pressure-sensitive, planar latching switching layer disposed between the electrodes, and a planar display layer disposed between the electrodes and in electrical contact with the pressure-sensitive, planar latching switching layer. The angle of orientation may preferably be such that the first and second arrays of conductors are essentially orthogonal.

Furthermore, the switching layer may be such that a voltage applied between at least one of the conductors of the first array and at least one of the conductors of the second array is operative to close the switch area of the planar latching switching layer between the conductors to which the voltage is applied, and to activate a corresponding area of the planar display layer. In such a touch screen, the areas between the conductors to which voltage is applied, preferably define the pixels of the touch screen.

In the touch screens described above, the switching layer may be such that the action of pressure on an area of the layer is to open closed switch regions within the area, or according to alternate embodiments, to close open switch regions within the area.

There is further provided in accordance with yet another preferred embodiment of the present invention, a touch screen as described above, wherein the position of the pressure is determined by measurement of the impedance between at least one of the conductors of the first array and at least one of the conductors of the second array. Alternatively and preferably, the position of the pressure may be determined by sequential electronic scanning of the first array of conductors and the second array of conductors to detect impedance changes between any pair of conductors, one from the first array of conductors and one from the second array of conductors.

In accordance with still more preferred embodiments of the present invention, there is provided a touch screen as described above, wherein the switching layer is such that the action of pressure to open the closed switch regions within the area is also operative to change the optical state of the display layer associated with the switch regions. Alternatively and preferably, where applicable for the type of switched layer used, the action of pressure to close the open switch regions within the area, may also be operative to change the optical state of the display layer associated with the switch regions.

In any of the above-described touch screens, the planar display layer may preferably be a liquid crystal layer.

### BRIEF DESCRIPTION OF THE DRAWINGS

The present invention will be understood and appreciated more fully from the following detailed description, taken in conjunction with the drawings in which:

FIG. 1 schematically illustrates a latched planar switch, constructed and operative according to a preferred embodiment of the present invention;

FIG. 2 is a schematic circuit diagram used to determine the characteristics of the planar latched switch of the type shown in FIG. 1;

FIGS. 3A and 3B are schematic views of an array of molecules with permanent electric dipole moments. FIG. 3A shows the molecules randomly oriented, while FIG. 3B shows the molecules oriented by the application of an electric field;

FIG. 4 is a graph schematically showing the optical transmission of an LCD as a function of the applied voltage;

FIG. 5 illustrates schematically a prior art active matrix TFT array, used to address the pixels of a liquid crystal display;

FIG. 6 is a schematic drawing of a passive LCD and switch display assembly, constructed and operative according to a preferred embodiment of the present invention;

FIG. 7 is a schematic drawing of the manner in which the data signals, used to define the image by means of the switches' state, are written to the columns and rows of a display array according to a preferred embodiment of the present invention;

FIG. 8 is a schematic illustration of a passive LCD and switch display assembly, constructed and operative according to another preferred embodiment of the present invention, which uses an LC layer adapted to operate also as the latched switching layer, and yet is able to overcome the problem of shorting between drive lines;

FIG. 9 shows a schematic view of a prior art color display, showing a color pixel made up of three sub-pixels of the three primary colors, the sub-pixels lying side by side;

FIG. 10 schematically shows a novel subtractive color display, constructed and operative according to a preferred embodiment of the present invention;

FIG. 11 schematically illustrates a touch screen display, constructed and operative according to a first preferred embodiment of the present invention;

FIG. 12 is a schematic illustration of an independent touch panel layer, according to another preferred embodiment of the present invention, for mounting on top of a display screen; and

FIG. 13 shows a schematic drawing of a touch screen display similar to that shown in FIG. 11, but including between the liquid crystal and switch layers, a thin, solid layer of a material conductive only in the z direction and not in the x or y directions.

### DETAILED DESCRIPTION OF PREFERRED EMBODIMENTS

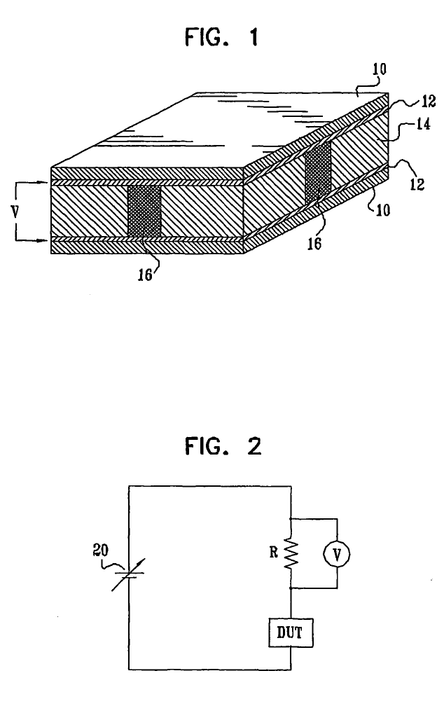

Reference is now made to FIG. 1, which schematically illustrates a latched planar switch, constructed and operative according to a preferred embodiment of the present invention. The device is composed of a pair of substrates 10, preferably made of glass, quartz, polyethylene, polyester, or a similar thin insulating material in the form of a sheet, between which is sandwiched a layer of switching material 14. The switching material 14, according to another preferred embodiment of the present invention, is a metal loaded epoxy, made by adding a suspension of metallic silver, iron, gold, copper, zinc, aluminum or another similar metal to an epoxy mixture before curing. The epoxy can preferably be Epon Resin 828, supplied by the Shell Chemical Company of Houston, Tex., USA, with Cap-cure 3-800 hardener. The chemical composition of this, and of many other suitable epoxy resins, is bisphenot A/epichlorohydrin with a trimercaptan cross-lining catalyst. However, the invention can also be executed using other resins such as triphenylolmethane triglycidyl ether, and other commercial cross linkers besides trimercaptan. Furthermore, solvents such as toluene, iso-propyl alcohol, ethanol, propylene glycol methyl ether acetate (PMA) can be used to provide a workable consistency for preparing the layer. In addition, according to other embodiments, a mediator such as ferrocene or ferrocene carboxaldehyde can also be advantageous in preparing the switching material. According to other preferred embodiments of the present invention, the switching material can preferably be made by dispersing the conducting material in the epoxy resin without curing it, i.e. without addition of the hardener. According to another preferred embodiment, the insulating material can be a viscous gel, such as Sylgard 516, a high viscosity silicon gel supplied by the DuPont Chemical Company, of Wilmington, Del., USA, or another RTV silicone compound. If silver is used as the conducting material, it can preferably be in the form of paste, such as Type 6462 Conductor, supplied by the DuPont Chemical Company, of Wilmington, Del., USA. The metals may also be in the form of a finely divided powder, or a colloidal suspension. Any similar and equivalent components, as known to those familiar with the art, may generally be substituted for the preferred types mentioned hereinabove, so long as they do not detract materially from the operation of the device.

The outer surface of each substrate sheet 10 is preferably coated with a thin layer 12 of a transparent conducting material, such as Indium Tin Oxide (ITO), as is known in the art, operative as transparent electrodes. Such substrates, already coated with the conducting electrodes can be supplied from a number of vendors, such as NeoVac, Inc. of Santa Rosa, Calif. The substrates are preferably aligned such that the electrodes are in direct contact with the switching material and the switch driving voltage V is connected to these electrodes. The thickness of the layer of switching material, for those switches in which the switching material is spread and squeezed, can be controlled by the use of spacer elements 16 of the desired size, disposed between the substrates. Convenient thicknesses of the switching material layer for such devices can preferably be in the range of 20 to 100 μm, in which range, the threshold switching voltages for concentrations of around 5% silver in cured epoxy are approximately in the range from 30 to 60 volts.

For those switches in which the switching material is applied by spin coating, the spacers are not generally required, and the layer thickness is determined by the characteristics of the coating procedure and the material. Convenient thicknesses of the switching material layer for such devices are much thinner and are preferably in the range of 50 nm to 2 μm. It should be emphasized, though, that these thicknesses and typical threshold voltages mentioned above are not limiting, and that with thicknesses outside of these ranges, and with switching voltages commensurate for those thicknesses, the latching switch also operates satisfactorily.

Reference is now made to FIG. 2, which is a circuit diagram used to determine the characteristics of a planar latched switch according to preferred embodiments of the present invention. The device under test, DUT, is connected in series with a variable voltage source 20, and a high impedance resistor R. The current through the device is determined by monitoring the voltage drop across the resistor R. So long as the applied DC voltage is lower than some threshold value Vₜₕ, it is found that there is essentially no measurable current flow, all of the voltage falling across the device, i.e., the device acts as an open circuit. Alternatively and preferably, an AC source can be used for characterizing the switch. When the applied voltage exceeds Vₜₕ, most of the applied voltage is seen to fall on the high impedance series resistor, R, i.e. the device acts as a low resistance. The level of this low resistance is typically of the order of 10 kohm to 1 Mohm, depending on the parameters of the switch, such as, though not limited to, the switching material constituents, the conductive material concentration, the thickness and area of the switch, as described above. The switch can thus be modeled as a capacitor in parallel with a latched resistor, which has a high impedance below threshold and which latches to a low impedance above threshold.

There are a number of different types of preferred embodiments of latching switches according to the present invention, whose characteristics determine the memory duration of the switching transition in the switching material. These embodiments differ in the methods of production used and in the materials used for the switching layer. In this way, it is possible to define five different preferred embodiments of latched switches, though these embodiments are only examples of the switches prepared, and there are many other possible combinations of materials and thicknesses with which the invention is also operative.
1. According to a first embodiment, the latched switch has the following properties:
   (i) Switching Material: bisphenol A/epichlorohydrin resin with trimercaptane or another commercial cross linker, with toluene or iso-propyl alcohol as a solvent; or
      Triphenylolmethane triglycidyl ether without any cross linker and with propylene glycol methyl ether acetate (PMA) as a solvent.
   (ii) Process: Spin coated preferably to a thickness between 60 nm and 500 nm.
   (iii) Switching characteristics: The material is open circuit when no voltage is applied, and switches to a closed circuit at a high enough voltage level.
   (iv) Classification: The closed state remains after removal of the switching voltage for a period of seconds to minutes, and in some cases, even for hours. It is thus classed as an FM switch. Moreover, application of a small AC voltage after removal of the switching voltage enables the closed state to be sustained for many hours, and hence also classifies the switch as an SM type.
2. According to a second embodiment, the latched switch has the following properties:
   (i) Switching Material: bisphenol A/epichlorohydrin resin with trimercaptane or another commercial cross linker, with metallic colloidal additives.
   (ii) Process: Spread and squeezed, preferably to a thickness between 20 and 100 μm.
   (iii) Switching characteristics: The material is open circuit when no voltage is applied, and switches to a closed circuit at a high enough voltage level.
   (iv) Classification: The closed state remains after removal of the switching voltage for a period of minutes. It is thus classed as an FM switch.

Moreover, application of a small AC voltage after removal of the switching voltage enables the closed state to be sustained for many hours, and hence also classifies the switch as an SM type.
3. According to a third embodiment, the latched switch has the following properties:
   (i) Switching Material: bisphenol A/epichlorohydrin resin with trimercaptane or another commercial cross linker, with ferrocene or ferrocene-carboxaldehyde as a mediator, and with metallic colloidal additives.
   (ii) Process: Spread and squeezed, preferably to a thickness between 20 and 100 μm.
   (iii) Switching characteristics: The material is open circuit when no voltage is applied, and switches to a closed circuit at a high enough voltage level.
   (iv) Classification: On removal of the switching voltage, or its reduction to a very low value, the switch returns to its high impedance state within a range of from a few hundred microseconds to a few milliseconds. It is thus classed as a PM switch.
4. According to a fourth embodiment, the latched switch has the following properties:
   (i) Switching Material: Commercial RTV silicone gel, with aluminum powder dispersed in it before curing.
   (ii) Process: Spread and squeezed, preferably to a thickness between 20 and 100 μm.
   (iii) Switching characteristics: The material is open circuit when no voltage is applied, and switches to a closed circuit at a high enough voltage level.
   (iv) Classification: The closed state remains after removal of the switching voltage essentially indefinitely. It is thus classed as an FM switch.
5. According to a fifth embodiment, the latched switch has the following properties:
   (i) Switching Material: Titanium butoxide based. This is the basic reactant, which serves as the source for the TiO₂ colloids. The titanium butoxide is mixed with dry solvents such as 2-propanol, or ethanol and then mixed with any of the following acids to form the TiO₂ colloids:
      5N Hydrochloric acid
      Nitric acid at pH2
      Acetic acid at pH3
   (ii) Process: Spin coated preferably to a thickness between 60 nm and 500 nm
   (iii) Switching characteristics: The material is open circuit when no voltage is applied, and switches to a closed circuit at a high enough voltage level. The switch can be reset to its open state by application of a signal with a high frequency content. For example, if the switch was closed with a triangular wave of frequency 100 Hz, it can be reset to its low conductivity state by using a rectangular waveform of the same frequency or higher, since such a waveform has the required high frequency content. It is thought that the erasure mechanism may be due to a sharp change in voltage, i.e. a voltage pulse Hence when applying a rectangular voltage pulse, which contains voltage gradients far greater than those in the corresponding triangular voltage pulse, the switch resets, whereas using the same amplitude triangular voltage pulse, it retains its state.
   (iv) Classification: This is a bistable element, which is closed with one waveform and opened with another. Its state is sustained with the original triangular waveform, even if the amplitude is lowered. Its state remains when the switching voltage is removed for a period of minutes, thus classifying it as an FM switch. Application of a small AC voltage after removal of the switching voltage results in the closed state being sustained up to many hours, such that the switch is also classified as an SM switch.

Erasure can be performed immediately by using the appropriate waveform.

As has been described above, the time following removal of the exciting voltage, during which the switch remains closed before returning to its unexcited open state, is mainly dependent on the composition of the switching material. As already intimated, addition of some types of elastomers to the mixture shortens the closed duration time, after the applied voltage has been removed. Thermal heating or physical pressure on the device also shorten the time that the device remains in its excited, closed state.

Finally the value of the threshold voltage Vₜₕ is dependent on several independent parameters, as follows:
(a) The concentration of the conducting material in the switching material—there is some indication that the higher the concentration, the lower Vₜₕ.
(b) The thickness of the switching material layer—the greater the thickness, the higher Vₜₕ.
(c) The physical pressure applied to the device—the greater the applied pressure, the higher Vₜₕ.
(d) The temperature of the device—there is indication that the higher the temperature, the higher Vₜₕ.

From measurements made on a number of switching materials, it has been observed that there is a noticeable tendency for the threshold voltage to rise with increased thickness of the switching material, and to fall with increasing concentration of the conducting material. Furthermore, it appears that the resistance of the closed switch decreases with increasing concentration of conductive material.

According to a further preferred embodiment of the present invention, the switch may also behave as an optical switch. Thus, when the switch is closed by application of the requisite drive voltage, which in the case of the optical switch, can be lower than the threshold voltage required for an equivalent electrical switch, the switching material appears essentially transparent to visible light. When-the switch is open, on the other hand, the switching material has an opaque appearance, which effectively reduces the optical transmission to a negligible level. The device thus behaves as a latched optical switch in addition to its electrical latching switch properties. Preferred materials for use as the insulating basis of the switching material for such an optical latched switch, include preferred types of epoxy resins in an uncured state, i.e. without the addition of the hardener. According to one preferred embodiment, a 10% concentration of the Type 6462 Conductor silver paste mentioned above, in Epon Resin 828, also mentioned above, without the addition of any hardener, produced good optical switching action. In general, it has been found that among the materials operative for such optical switches, the use of liquids or semi-liquids as the insulating material, provide the best performance, according to these preferred embodiments of the present invention.

Such latching optical switches can be advantageously used as the directly driven, active imaging elements in a flat screen display, without the use of any additional liquid crystal elements therein.

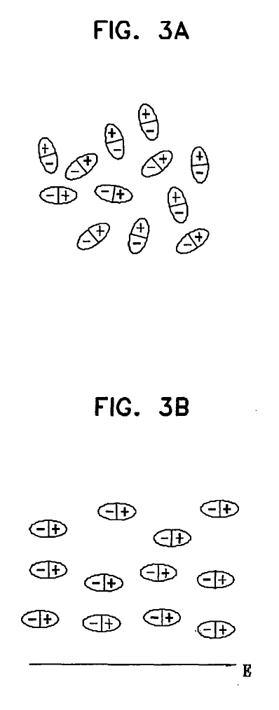

A possible explanation of the behavior of the switching materials which include additions of conductive materials, according to the various preferred embodiments of the present invention mentioned hereinabove, whether electrical or optical, can be supplied by assuming a polar alignment of a dielectric component, associated with the metallic components of the material. The application of the switching field causes the electric dipole moments to align with the field direction, aligning the metallic particles with them, and thus providing a conduction path for the switch current. The optical properties can also be thuswise explained, whereby alignment of the dipolar molecules causes a clear, or a clearer optical transmission path through the device in the direction of the field. The effect of pressure on the devices may also be explicable by this model, since the application of pressure will cause the aligmnent to be perturbed, thus requiring a higher voltage to realign the dipoles and restore full conductivity. The alignment model is shown in FIGS. 3A and 3B, which are schematic views of an array of molecules with permanent electric dipole moments. FIG. 3A shows the molecules randomly oriented, before application of any field, while FIG. 3B shows the molecules oriented by the application of an electric field E. As is observed, according to this model, the aligned dipoles would be operative in providing a more efficient conduction path via the associated metallic particles, and a better optical transmission path. A possible explanation of the behavior of the thin layers of switching materials which do not include any additions of conductive materials, is that under the influence of the switching field, the material undergoes a structural phase change, changing from an amorphous to the crystalline state. It is to be understood, however, that the present invention, in all of its embodiments, can be carried out irrespective of the nature of the physical process actually operative in the devices.

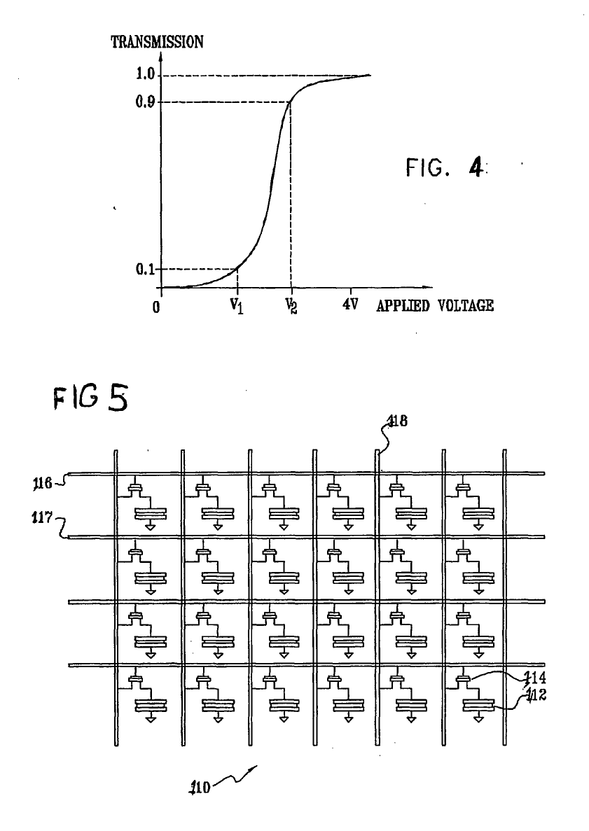

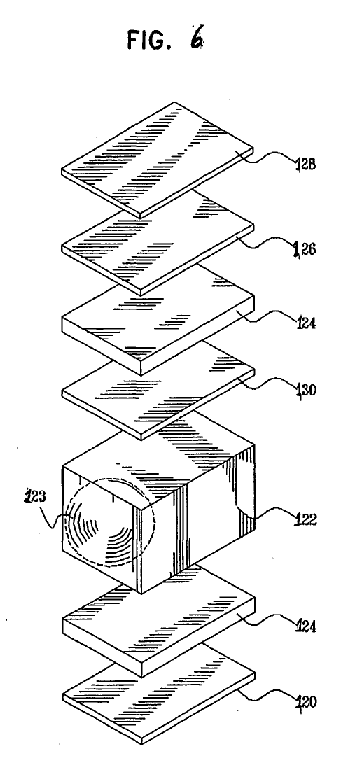

Reference is now made to FIG. 4, which is a graph schematically showing the optical transmission characteristic of an LCD as a function of the applied voltage. The voltage curve shows a typical low plateau level below the voltage VI, at which plateau, the element does not transmit, and a sharp transition region in which the element switches to its transmitting state, above the value V₂. The steepness of this transition region is what determines the number of elements which can be multiplexed in a passive LCD, as explained above in the background section of this application, in connection with the theory of Alt and Pleshko. The curve in FIG. 4 is shown for a normally off (normally black mode) LCD, but it is to be understood that the invention is equally applicable for use with a normally on LCD (normally white mode), the difference being that the transmission curve goes from maximum brightness at the lower voltages, to minimum brightness at the higher voltages. This is due to the polarizers of the LCD being in a crossed state, as opposed to the parallel state. It is further understood that although the curve in FIG. 4 is shown for an LCD device, other switching imaging elements showing similar switching characteristics, passing from an open to a closed situation, or vice versa, by means of a more or a less gradual voltage transition region, and behaving in a similar manner as a function of the applied switching voltage, may also be preferably used in the present invention.

Reference is now made to FIG. 5, which illustrates schematically a prior art active matrix TFT array 110, as used to address the pixels of a liquid crystal display. In such a display, the multiplexing limitation of passive displays is alleviated by sandwiching between the electrodes of each pixel in addition to the liquid crystal material (omitted from the drawing for clarity), a capacitor 112 and a thin film transistor 114, where the transistor is in series with the liquid crystal material, and the capacitor is in parallel with the liquid crystal material. The TFT is used as a means to buffer the liquid crystal pixel from the circulating drive voltages when the pixel is in its non-selected state, which, for a display having N rows, occurs N−1 times per cycle. The parallel capacitor is used to maintain the voltage across the liquid crystal material when it is in its non-selected state.

A row of pixels is selected by applying the appropriate select voltage to the select line 116 connecting the TFT gates for that row of pixels. Once a row of pixels is selected, each pixel in that row can be addressed by means of the desired voltage applied to the columns addressing the TFT via the data line 118. When a pixel is selected, it is necessary to apply the required voltage to that pixel alone and not to any non-selected pixels. Those non-selected pixels should be completely isolated from the voltages circulating through the array necessary to drive the selected pixels. Ideally, the TFT active matrix can be considered as an array of ideal switches, having zero closed resistance, and infinite open resistance. The operation of such an active matrix is as follows:
(a) Appropriate row select voltages are applied to the gates of the first row 116 of TFT's, while non-select voltages are applied to the TFT gates in all of the other pixel rows.
(b) Data voltages are applied at the same time to the column electrodes to charge the capacitor of each pixel in the selected row to the desired voltage, i.e., to on- and off-voltages, according to the status desired of that pixel.
(c) The row select voltage applied to the gates in the first row of TFT's is changed to a non-select voltage, and the row select voltage is then applied to the second row 117.
(d) Steps (a) to (c) are repeated for each succeeding row until all of the rows have been successively selected, and the pixel capacitors charged to the desired voltages, on or off voltages. Thus, in every cycle, data is written to each of the pixels of the entire LCD.

A 1000×1000 pixel monochrome active matrix LCD has 1 million TFT's and requires 2000 connections to external drive circuitry. A color display has three times as many connections. Such arrays are thus complex and costly to manufacture, and production yields may be accordingly low. Furthermore, the need to write data to every pixel in every cycle necessitates the processing and routing of a large quantity of addressing signal information, which involves complicated circuitry and a comparatively high power dissipation.

Reference is now made to FIG. 6, which is a schematic drawing of what is here termed, a quasi-active LCD, constructed and operative according to a preferred embodiment of the present invention, which provides the performance advantages of the prior art active matrix TFT array LCD shown in FIG. 5, but without the disadvantages arising from the complexity of those devices. This novel display embodiment is only marginally more complex to construct than a passive matrix LCD, thereby engendering significant cost savings over an active matrix TFT array display.

The LCD of this embodiment has the same base structure as that of a conventional passive LCD, and preferably includes a front surface polarizer 120, a liquid crystal material 122, whose thickness is determined by spacers 123 sandwiched between two glass cover plates on which the electrodes are printed 124, the electrode conductors running in directions orthogonal to each other, to define the pixels at their cross-overs, a polarization analyzer 126, and, for the case of a reflective LCD, a mirror 128. The LCD of the present invention differs, however, from the basic structure of a prior art passive LCD in that a transparent latching switch layer 130 is added. This layer is preferably constructed of a layer of switching material, sandwiched between an electrode 124 on one side and the liquid crystal material on the other. The composition of the switch is preferably chosen such that the switch is transparent in the visible range. Though the latching switches described in this application hereinabove are suitable for use in these flat panel display embodiments, it is to be understood, however, that the present invention is equally operable with any suitable prior art or future type of latching switched device.

The effect on the latching switch, of the voltages applied to the various pixels of the LCD, is a localized effect. The switch closes only at those locations where the voltage (or E-field) arising from the voltage applied to the LCD pixels situated immediately above (or below) that location, exceeds the switching threshold level according to the preferred embodiment being considered. The voltages applied to the rows of the LCD pixels are either 0 or ⅔V, and those applied to the columns are either ⅓V or V, where V is a voltage greater than the switching threshold, and is determined according to further limitations to be described below. For the latching planar switch layers described in this application, the value of V ranges typically from millivolts to hundreds of volts, depending on the thickness of the switching layer and the metallic doping level.

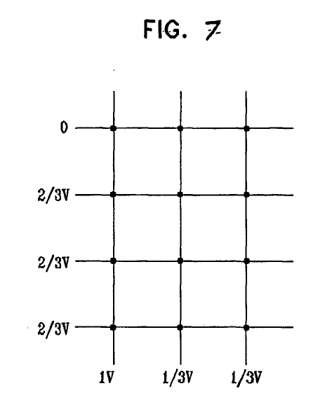

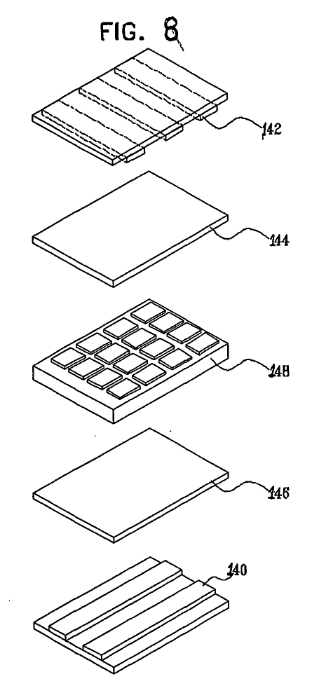

Reference is now made to FIG. 7, which is a schematic drawing illustrating the procedure of writing the data signals used to define the image, to the rows and columns of the display of the preferred type shown in FIG. 6. In the select state, a row that is selected has zero voltage applied, and all the other rows preferably have a voltage of ⅔V applied at that point in time. Any pixel in the selected row, which is to be turned black, i.e. is to be turned on, has a voltage V applied to the column of that pixel. All pixels which are not to be black, have a voltage preferably at a level of ⅓V applied to their column. As a consequence, every pixel which is to be turned on has a voltage V across it, this being the difference between the voltages applied from the row and column of that pixel. Since the voltage V is greater than the threshold voltage, this closes the latching switch. All the other pixels have a voltage of ⅓V across them, this being the resultant of row and column voltages. Since ⅓V is less than the threshold voltage, this voltage will not thus close the pixel to which it is applied.

The voltage on the first row is then switched to ⅔V, and the voltage on the second row is reduced to zero, so that the second row data can be written. Again, the column voltages are applied according to the pixels to be selected to be closed or to remain open. The latching property of the switching array ensures that each closed switched pixel area in previous rows remains closed for a significant time even after removal of its switching voltage. It is the above properties which give the display of the present invention the ability for the data to be written to every row, one at a time, without affecting the data written to the previously written rows. Thus, after a single data writing cycle, all the pixels that are to be turned on have their associated switch pixels closed, and those which are not to be turned on, have their switch pixels open. This process constitutes the action of writing the data signal, which defines the image to be shown over the whole of the display. In fact, as each pixel writing signal is applied, the display pixel itself may be turned on momentarily, since the threshold voltage is generally significantly higher than the LCD switch-on voltage V₂, but this is merely an artifact which does not affect the correct operation of the display. Though the above data writing procedure has been described in terms of voltages of magnitude ⅓V and ⅔V, this division of voltages giving the broadest range of tolerance to the applied voltages, it is understood that the invention is not limited to these voltages but is equally operable with any combination of voltages whose difference gives the correct voltage across the selected pixels for closing or opening the switches.

Once the image information writing cycle is over, the pixel writing voltages are removed, and the latching property of the switching array ensures that each closed switched pixel area remains closed for a time generally significantly longer than the cycle time, even after removal of its switching voltage. Alternatively and preferably, the switching voltage is not reduced completely to zero, but is reduced to some small residual value, sufficient to keep the closed switched areas positively closed for almost infinite time without any danger of their opening. This mode of operation is known as a sustained memory mode, as will be further discussed hereinbelow. At this point in time, the result is a switching device, divided up into pixelated areas, the switch in each area being either open or closed according to the previously applied writing pattern which represents the image to be displayed on the LCD for that period of time. The pixelated areas may be virtual pixels, if the switch layer is preferably a uniform, physically unpixelated layer, and the pixelated areas therein are only generated by virtue of the voltages applied to the juxtaposed LCD pixels.

Once the written image has been set up in the matrix of switch pixels, according to this preferred embodiment of the present invention, an activation signal is then applied to each cell in the matrix. This activation voltage, termed V_{act}, may be an AC or a DC voltage, whose amplitude is greater than V₂, where V₂ is the voltage required to positively switch the LCD pixel, as shown in the LCD transmission curve in FIG. 4. This activation voltage is applied simultaneously to the entire switch matrix, preferably by connecting all the row conductors on the one hand and all the column conductors on the other hand, and applying the activation voltage between them. All those LCD pixels whose associated switch pixel area had previously been left open, will now receive zero volts across the liquid crystal material, since essentially the entire voltage will fall across the open switch. These pixels will therefore be off. Those LCD pixels whose associated switch pixel were rendered closed in the writing phase, will receive essentially the entire applied voltage V_{act}, and will thus switch on, since the associated switch is closed and thus does not bear any meaningful voltage drop across it. The value of the activation voltage V_{act} must be chosen to be significantly less than V, so that when the activation voltage is applied, it does not affect the state of the switches. The activation voltage may, however, be operative in holding those switches which are closed in their latched close state.

This mode of operation of an LCD flat panel, according to this preferred embodiment of the present invention, can be termed a method of pixel driving using a closed switched mode, or a quasi-active mode of operation. The use of this preferred method, incorporating a latched switching layer in contact with the display layer, results in a number of very significant advantages over prior art displays:
1. The number of rows which can be written to this passive type of display is theoretically unlimited, since the writing is done to a device having memory, and there is no appreciable decay of the written information with time while more and more pixels are sequentially written. This is in contrast to TFT technology wherein the devices, although acting as either a closed or open switch when addressed, do not possess any inherent memory.
2. The contrast is much greater than that achievable with passive display multiplexed prior art writing, where the contrast has to be sacrificed for an increase in the number of rows, due to the RMS response nature of such displays, and the lack of memory.
3. In the activation mode no data is written. The activation mode can be considered as an operating or holding signal, operative only in order to respectively turn on or to maintain the LCD pixels in their on state, whereas the data needs to be written only when the data is changed, thereby closing or opening the switches. Thus for applications such as bill boards or information signs, or the like, where the data are updated infrequently, the data need be written-in only once, and thereafter disconnected, since the activation signal holds the image on. Since this activation signal has no information content, the required circuit structure is little more complex than a conventional passive LCD display. However, the information handling capabilities generally need be significantly less than for a conventional passive LCD display, since only rows which require a change in their information content need to be rewritten every cycle, which is typically 30 msec. There is therefore far less information flow on the computer bus, than in conventional passive LCD displays. In word processing applications on a PC, for instance, the images displayed can be considered to be quasi-static, since data updating takes place significantly more slowly than every 30 msec. Consequently, in most computer applications, except for those with a high video content, this method of writing the display information, according to preferred embodiments of the present invention, is very favorable.
4. It is possible to utilize liquid crystal devices whose response is much faster than those used in prior art passive displays. Thus, rapid, high switching speed, twisted and super twisted nematic LCD's may be used, since the activated liquid crystal pixels receive a voltage greater than or equal to their activation voltage continuously, and the off pixels receive a zero voltage continuously, due to the open switch associated with them. This situation is unlike the case of RMS-responding LCDs, where the on pixels receive an ‘on’ voltage only in the RMS sense, and not continuously, and the ‘off’ pixels receive, generally, a non-zero RMS voltage.

This preferred embodiment of the present invention is essentially a novel method of powering display screens by first writing the information to be displayed by closing the appropriate switches, and then supplying the power to drive the relevant pixels on, by means of an AC or DC signal with no information content whatsoever. In prior art active matrix displays with TFT drivers, the image information is written in each cycle, such cycles being known as the refresh cycle. Since each cycle requires powering of the transistors and recharging the capacitor associated with each TFT, such displays dissipate a lot of power, which serves no useful purpose other than to provide the refresh state. According to the present invention, the information needs be written only when it changes, and the switch barely consumes power after being turned to its steady state position, thus making the drive circuits simpler, and making a significant power budget saving.

A major power consumption in LC applications is expended in the switching of the drive voltage, since the LC material acts as a capacitor, which must thus be recharged every time the drive voltage is changed. Furthermore, since the LC material may be harmed by the long-term application of a DC voltage, the DC component of the voltage across the LC material must be kept as close as possible to zero. The voltages across the LC material are thus designed to be AC only, and at a frequency chosen such that the LC switching rate is faster than the LC response time, which is of the order of 10's to 100's of milliseconds. By choosing such a frequency, the LC responds to the RMS of the switching voltage and not to the instantaneous voltage. Based on these typical values of response time, a suitable frame refresh rate is preferably of the order of 30-100 Hz. However, due to the operational requirements of passive displays, such as those often used in cheaper LC devices, the LC voltage has to be switched at rates which are much higher than the frame rate. The reason for this is that the display is scanned row by row, and every pixel that is on receives a switching voltage and every off pixel receives an off voltage. Thus even when a row is in the non select state, the voltage across it is switched. If there are N rows in the display to switch, the effective switching rate across the pixel is thus up to N*f, where f is the frame rate. Consequently, although the frame rate of the screen may be only some tens of Hertz, the effective switching rate across each pixel may be up to many kiloHertz for a display with just several tens of rows. Consequently, a significant level of power will be consumed in the charging and discharging of the capacitor, due to dissipation in stray resistances present in the circuit.

However by using displays constructed according to preferred embodiments of the present invention, where the information is written only once, when the appropriate switches are closed, the effective switching frequency across the pixels may be f*N, in the worst case, but this is done once only per image. Afterwards, a much lower frequency voltage is applied to merely power the device with all of the rows,short circuited to each other, and likewise for the columns). This frequency could be as low as the frame rate, f, since the power is applied to every pixel in the entire screen simultaneously. Since the major energy consumption in such passive LCD's is expended in charging the LC capacitors, and this charging frequency is now reduced effectively from f*N to f, the saving in drive energy is very high, being reduced approximately by a factor equal to the number of rows in the display.

In order for the above-mentioned switching mechanism of the image information writing cycle to be optimally operable, there are limitations to the open and closed resistances of the switch layer, compared with the resistance of the liquid crystal layer. If R_{LC} is the resistance of the liquid crystal material, R_{Switch}_{_{—}}_{Off} is the resistance of the switch in its open (off) state and R_{Switch}_{_{—}}_{On} is the resistance of the switch in its closed (on) state, it is preferably required that:
R_{Switch}_{_{—}}_{Off}>>R_{LC}
R_{Switch}_{_{—}}_{On}<<R_{LC}

This requirement is the ideal state and results in optimum efficiency. However this selection may cause problems in the reopening of the switch because the opening and closing voltages required by the switching device are often close in value. Hence, if in the closed state the impedance of the switch is very low, it will receive only a small fraction of the applied voltage. Thus the switching voltage which needs to be applied to the switch in series with the liquid crystal, in order to open the switch, will be unreasonably large compared with the voltage used to close the switch. In order to alleviate this problem, the display device may also be operated satisfactorily if both the on and off resistances of the switch are arranged to be greater than the impedance of the liquid crystal. The switching voltages for opening and closing the switches would then not be too different, since most of the voltage would be developed across the switch. However, according to this preferred embodiment, for the on pixels, the power efficiency would be reduced due to a significant level of the power being dissipated across the switch.

There are, however, alternative solutions to this problem, according to further preferred embodiments of the present invention In a first solution, according to a preferred embodiment of the present invention, the closed switch may be turned off, returning from its state of high conductive to a high impedance state, by means of a signal of different nature to that of the closing process, such that the resetting is performed by a different mechanism. Thus, for instance, the tuning off may be actuated by a current mechanism, where the turning on was executed by a voltage mechanism.

A second preferred solution is applicable using the novel switching materials described hereinabove, where there are described some switching material configurations which return to their open state fairly rapidly after removal of the switching voltage, within a time scale measured in the millisecond range or less, which is generally less than the cycle refresh rate of the display. Consequently, when the activation voltage is removed once the frame has been displayed for the predetermined time required, the display pixels return to their off, or white, state within their characteristic decay time, typically a number of milliseconds for commonly used LCD's, and the switch pixels which were closed also return to their open state within the above-mentioned time scale measured in the millisecond range. This then obviates the necessity of applying any significant opening voltage to the switch, and hence also obviates the necessity of making even the closed impedance of the switch higher than that of the display element.

A number of the novel switching material configurations described hereinabove may be alternatively and preferably used in order to accomplish this more efficient mode of operation of the display, as follows:
(i) A sustained memory (SM) configuration of switch material, in which the closed state is maintained only if a sustaining voltage is applied to the switch, under which conditions, it can maintain its conductive state for very long periods. This embodiment is acceptable provided that, on removal of the sustaining signal, the switch returns rapidly to its open state. Generally the SM switches are only committed to remaining closed while a sustaining voltage is present, and not all of the SM configurations reset rapidly upon voltage removal.
(ii) A partial memory (PM) configuration of switch material, in which the closed state is maintained after removal of the switching voltage typically for a few milliseconds. The switching voltage, which is generally AC in form, is thus applied to the pixel, and on its removal, the pixel switch turns off within the characteristic PM time scale, without application of any positive turn-off voltage. For proper use of PM switches with AC switch driving voltages, it is necessary to ensure that the frequency of the drive signal be high enough so that the voltage is near the zero level for a period shorter than the turn off time of the PM element.
(iii) Titanium butoxide based switch material containing TiO₂ colloids. Such a switch can be reset to its open state by application of a signal with a high frequency content. For example, if the switch was closed with a triangular wave, it can preferably be reset to its low conductivity state by using a rectangular waveform of the same frequency or of higher frequency, since such a waveform has the required high frequency content.

Use of any of the above mentioned preferred switch materials thus enables the information in switched on pixels of a display, according to the various embodiments of the present invention, to be erased, and the pixels switched off again in an energy efficient manner, after removal of the activating voltage, and at a refresh rate sufficiently quick for normal human vision. Furthermore, the erasure procedure need not be performed for the entire image, but can be applied selectively for specifically chosen pixels or rows. The erasure procedure can be considered as a definite voltage application step, with the voltage actually used being dependent on the type of switch used. For the SM configuration, the applied voltage is any voltage less than the sustaining voltage, for the PM configuration, the applied voltage is an effectively zero voltage for a sufficient time, and for the TiO₂ colloidal additive switch configuration, the applied voltage is a waveform of the correct shape and frequency, such that it contains the required high frequency component.

It is to be emphasized that although the above-mentioned preferred embodiments have been illustrated using an LCD in series with a latching switch of the novel type described hereinabove in this application, the present invention is not meant to be limited to this combination, but is rather a new type of generic display driving technique, whereby the information is first inscribed on a switch array, and afterwards is transferred onto the imaging pixels by means of a common activating signal which operates the entire display according to the status of the switch pixels. The invention is thus operable with any type of latched switched array, including but not limited to, those described hereinabove, organic switches, glassy-type bi-stable switches, semiconductor array bi-stable switches, or any other suitable type. Some such types of switches are described in the article “Reproducible switching effect in thin oxide films for memory applications” by A. Beck et al., published in Applied Physics Letters, Vol. 77, pp. 139-141 (July, 2000), hereby incorporated by reference. Amongst the switch types mentioned there are films of amorphous chalcogenide semiconductors, amorphous silicon conducting polymers, ZnSe—Ge heterostructures, a variety of binary and ternary oxides such as Nb2O5, Al₂O₃, Ta₂O₃, TiO₂ and NiO, some ferroelectric heterostructures, such as BaTiO₃, and MIM (Metal-Insulator-Metal) structures with oxides such as (Ba,Sr)TiO₃, SrZrO₃, SrTiO₃, Ca₂Nb₂O₇ and Ta₂O₅ doped with up to 0.2% of Cr or V as the insulator layer. Some of these MIM structured switches show multilevel switching, wherein the resistance of the open or closed state is dependent on the length and amplitude of the individual write pulses used to switch the device. Furthermore, in the article “Memory effect in the current-voltage characteristic of a low-band gap conjugated polymer”, by D. M. Taylor et al, published in Journal of Applied Physics, Vol. 90, pp. 306309 (July 2001), there are described reversible voltage-induced bistable switching phenomena in a low band-gap polymer, poly(4-dicyanomethylene4H-cyclopenta [2,1-b:3,4-b′] dithiophene), known as PCDM. Here also, there is reported dependence of the impedance of the switched states with the drive voltage. In U.S. Pat. No. 3,241,009 for “Multiple resistance semiconductor elements” to J. F. Dewald et al., there are described glassy-type bi-stable switches, some of which have been observed to have more than two resistance states. Finally, molecular switches, such as those described by M. A. Reed and J. M. Tour in the article entitled “Computing with Molecules” published in the June 2000 issue of Scientific American, may also be suitable for application in the present invention.

According to another preferred embodiment of the present invention, the use of such switching devices which have a range of open or closed impedances, dependent on the drive voltages applied to the device, enables the switching of pixels of the displays of the present invention to various gray levels. By controlling the resistance of the closed state of the switch, the voltage drop across the liquid crystal element, or any other imaging device, may be controlled, since the LC or other imaging device element is in series with the switching element. According to these preferred embodiments, the brightness of the switched pixels may also thus be controlled.

In addition, the invention is operable with any sort of pixelated display panel having imaging elements with switching characteristics whereby the element changes from an open to a closed status by means of a voltage transition region. Such displays include, but are not limited to, LCD, phosphorescent and luminescent displays.

Table 1 above of prior art LCD displays, can thus be rewritten, to include an LCD according to the above described preferred embodiments of the present invention, having a contrast and number of rows greater than the prior art passive displays. The result is thus a display having properties typical of an active matrix type display, but with passive matrix display costs and manufacturability. The only constructional difference from a conventional passive matrix LCD is the addition of an extra layer, which, due to the local nature of the switching effect, emulates the effect of a switching device per pixel. This should enable the use of cheap passive displays in large area applications, and in applications requiring high resolution and contrast such as laptop computer displays, etc. In addition, such displays will improve many low-cost hand held applications due to the increased performance of the LCD display, without appreciable cost increase.

According to another preferred embodiment of the present invention, the liquid crystal layer itself is adapted so as to function as the latched switched layer of the display. This may preferably be achieved by dispersing conducting metal into the LC material itself, or by adjusting the thickness of the liquid crystal layer, preferably making it quite thin. In this mode of operation when the voltage exceeds the threshold value, the LC pixel itself becomes a closed switch element, and no voltage can be maintained across the LC element because it is short circuited. Thus, in contrast to the previously described embodiments, in the information writing cycle, when the relevant LC pixels are to be off, a voltage above the threshold voltage is applied to any pixel which is supposed to develop (steady state) no voltage across it thus closing that switch pixel and preventing the voltage from being developed to switch on the LC pixel. LC pixels which are to be switched on receive a low voltage, lower than the threshold voltage. This embodiment may, however, be problematic since the columns and rows of the drive electrodes may be short-circuited to each other because of the conductivity of the switch layer (which is now integrated into the LC layer) when a substantial part of the switched area is closed. The device will not then be able to operate as described above.

Reference is now made to FIG. 8 which is a schematic illustration of a preferred embodiment of the present invention, which uses an LC layer adapted to operate also as the latched switching layer, and yet is able to overcome the shorting problem. FIG. 8 shows the central section of the display, and comprises orthogonal sets of conductor arrays 140, 142, deposited on insulating substrates, for defining the pixel positions at their intersections, and for providing the row and column signals to the pixels. The LC imaging layer 144 is also operative as the latched switching layer, by the incorporation of dispersed metallic additions. The display shown differs, however, from the earlier described embodiments, by the addition of another thin layer of insulating material 146 located between the imaging element 144 and either of the conductor layers, to ensure that there are no short circuits between neighboring conductors in the rows or columns. Thus, when the activating voltage is applied between all of the row and column conductors, it is operative to turn the correct LC pixels off or on without short circuits. The insulating material and thickness is chosen to provide an impedance which is a compromise between the necessity to maintain the appropriate electrical contact between the various layers, and yet to provide sufficient resistance laterally to prevent short circuits between adjacent conductors. It is thus important to ensure that when the activation voltage is applied, after the information has been written, a sufficient level of voltage reaches the imaging device in order to turn on unshorted pixels, and yet is should not be too high, at a level that would cause the switch in the metallic laden imaging device, to close, and thus to short circuit that pixel. The correct level of impedance can be readily found by determining the voltage division across the series connected insulating layer and the metallic laden LC layer.

Reference is now made to layer 148 in FIG. 8. This layer is added in order to overcome the effect which can be described as overlocalized switching. In the previous embodiment shown in FIG. 6, there is a conductive layer, preferably of ITO covering the whole of the latching switch layer, such that when one part of a pixelated area of the latched switch layer is closed, the whole of that pixelated switch area is closed, for instance due to the presence of many conducting paths. According to the embodiment of FIG. 8, because of the presence of the insulating layer 146, it is possible that only that part of the active imaging element, exactly beneath the virtual conduction line, is short circuited, while the rest of the pixel, which is supposed to be short circuited, is not so because of the absence of a conductive layer between the insulating layer and the imaging element. This localized conduction is prevented by the addition of a pixelated checkerboard conductive layer 148, situated between the insulating layer and the imaging element. The layer is preferably vacuum deposited onto the surface of the thin insulating layer 146, and is preferably made up of a matrix of thin layers of a transparent conductive material, such as ITO, properly aligned such that effectively the area of each pixel is covered but not the inter-pixel areas. Thus, if there are areas of localized conduction on a pixel, the entire pixel is short circuited, due to the conductor matrix between the layers. The same pixelized matrix may also be useful for use in the embodiment of FIG. 6, if a very low doping level of metallic switching material is used in the latching switch layer, in order to spread the potential across the entire pixel, which without the pixelized conducting matrix, may have been localized only at a limited conduction path.

As with the previously described embodiments, an accurate voltage is not necessary either for the information writing stage, or for the activation step. This is so because after the switch is closed, it behaves as a short in comparison with the other impedances in the circuit, irrespective of the specific voltage that was used to cause it to short circuit. The only requirement is that the information writing signal be greater than the threshold voltage, and that the ratio of the maximal voltage required to close any switch to the minimal voltage required to close any switch does not exceed a factor 3. This ensures that no switch will be closed inadvertently and, on the other hand, no switch which needs to be closed will be missed. This arises from the known result that in passive matrix devices, the maximum instantaneous (not RMS) ratio that can be obtained between the voltage applied to a pixel in its select state and in a non select state, is three. For the activation step too an accurate voltage is not required. All that is needed is a voltage that is greater than the LC “turn on” voltage, and that the voltage be lower than the threshold voltage closing the switch. This is so because the switches are functional solely to determine whether the relevant LC element receives voltage or not. This is in contrast to passive matrix, RMS driven, LC devices where the on and off voltages have to be set rather accurately. If, however, accurate gray image levels are to be produced, using the above-mentioned variable switching element embodiments, and not only binary switched levels, a higher level of control is needed over the information writing voltages.

The present invention has been presented in terms of the provision of a novel flat panel display by use of latched switch arrays in serial electrical contact with the display elements. It should, however, be understood by one of skill in the art, that the solutions using such latched switches described hereinabove can also be applied to other devices besides displays, wherein a device is operated in series with a bistable or multi-stable switch according to one of the embodiments of the present invention. Such other devices could include, for instance, touch screens, keyboards, and other similar devices involving an element with alternate states of operation. In order to return the switch to its ground state, the generally used and known mechanisms of applying a negative pulse may not operate efficiently, since, when the switch is in series with another device, and is turned on, most of the applied switch-off voltage pulse would not fall across the switch, because of its low impedance in the closed state. Thus if the switch-off process is dependent on an E-field effect on the switch, it will not easily succeed.

According to the preferred embodiments of the present invention, switches of the sustained memory configuration, partial memory configuration, or of the TiO₂ colloidal additive type may be used in switching off these series elements at high switching efficiencies. Prior art resetable switches for use in device switching are generally three terminal devices, with the third terminal being a control electrode for switching the conductance of the path between the other two electrodes, for example, the gate electrode, for switching the conductance of the path between the source and drain in a gated transistor. The latching switches used in accordance with the methods of the present invention, on the other hand, are operable as two terminal resetable switches, and are thus able to improve the efficiency and especially to reduce the wiring complexity of such systems containing individual elements whose state is alternated according to the system requirements.

Reference is now made to FIG. 9, which is a schematic view of a prior art color display 210, showing a color pixel 212 made up of three different colored sub-pixels, showed in an enlarged form and marked R, G and B for the three primary colors. These three sub-pixels, R, G, B, lie side by side in the larger composite pixel 210. The display shown is self-luminous, as shown by the light rays 214 emitted from the display towards the viewer's eye 216. According to this prior art display, the color viewed is formed additively from the three primary colors displayed by the three sub-pixels, added in varied predetermined intensities to produce the desired color.

There is however an alternative method of producing a fall range of colors from base colors, and that is the subtractive process, as extensively used in the photographic and printing industries, and especially in the digital printing industry. In these applications, the efficiency and resolution required are generally significantly higher than those required of display monitors. These characteristics are achieved by displaying the basis colored pixels one on top of the other, as opposed to one beside the other, as in prior art additive system displays. By this means, each composite pixel need be no larger than the sub-pixel size, thereby immediately offering a three-fold improvement in resolution. Besides the improved resolution, the subtractive system is also capable of yielding a performance improvement in the form of greater light efficiency.

The color-mixing configuration in the subtractive process is different from that in the additive process. Subtractive systems involve colored dyes or filters that absorb power from selected regions of the spectrum, hence the name subtractive. Three filters are typically placed in series. Thus for instance, a dye that appears cyan when viewed with white light is one that absorbs long wavelength (red) light from incident white light, thus leaving the cyan to pass through. By controlling the amount of cyan dye or ink, the amount of redness in the image is controlled. This process is used in reflective media, e.g. photography, color printers. In color printing, the dyes of the printer inks absorb certain colors and any remaining color that is not absorbed creates the desired visible hue.

The achievement of a large range of colors in a subtractive system is generally performed by means of filters that appear colored cyan, magenta and yellow (CMY). Cyan in tandem with magenta produces blue, cyan with yellow produces green, and magenta with yellow produces red.

In the printing industry, whose products are rendered visible by light reaching the eye by reflection, the desired color is achieved by depositing one layer of color on top of the other, by means of the subtractive color system. In any technology that utilizes light by modulation of colored pixels located on top of each other, as opposed to pixels located beside each other, the subtractive color system must be employed.

In order to display colors via the Cyan Magenta Yellow (CMY) system, it is necessary to be able to form any convex combination of the CMY colors. This means that it should be possible to cause a fraction a of the color C to pass, a fraction β of the color M to pass and a fraction γ of color Y to pass, such that:
αα+β+γγ=1 and αα, ββ, γγ≧1
Practically, this means that if a display is to be implemented to include these characteristics, three optical elements respectively colored Cyan Magenta and Yellow, must be used in series, and each individual element must be capable of variation from full transparency, i.e. full light transmission, to any one of the single three colors, Cyan, Magenta and Yellow, at its maximum density. To the best of the applicant's understanding, this is not currently possible with liquid crystal materials, which are the most commonly used medium in flat panel displays. Such liquid crystal materials are only able to vary from full opacity, i.e. no light transmission, to any given color achieved by placing a filter over the liquid crystal imaging element (layer). Thus, such materials cannot extend their transmission level from any given color down to transparency. In order to implement a subtractive display monitor, which requires this property, a novel type of display construction and operation is thus necessary, as provided by the various preferred embodiments of the present invention described hereinbelow.

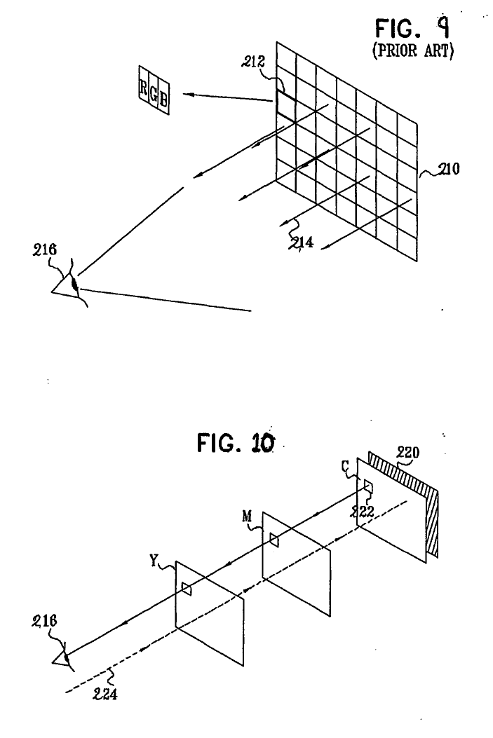

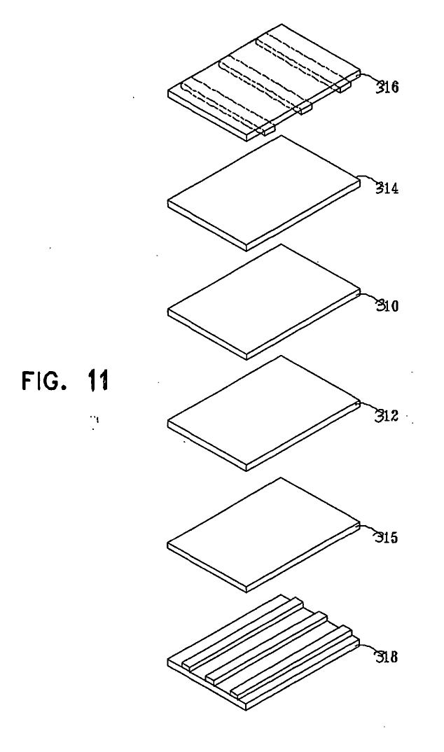

Reference is now made to FIG. 10, which schematically shows a novel subtractive color display, constructed and operative according to a preferred embodiment of the present invention. The display is a reflective display, and includes three variable color filters C, M and Y, serially disposed in front of a reflecting surface 220. Each of the filter elements is preferably constructed of a colored planar optically variable layer. One type of such a device is described hereinabove in the descriptions regarding the Latching Planar Switch embodiemnts. In those devices, the transmission of the device is not only electrically controllable, it is also latched, i.e. on removal of the voltages after changing its level of optical transmission, the device retains its latched color level for some time. It is to be understood, however, that the present invention is equally operable with any suitable type of planar colored transmissive device whose optical density is capable of being varied by means of a control signal, whether of the latching type or not.

According to this preferred embodiment of the present invention, the screen is made up of three layers of pixelated optically variable layers, C, M, Y, arranged in series, one on top of the other, with a reflective passive panel 220 behind them all. One of the layers C has dispersed conductive metallic particles colored cyan, the second M magenta, and the third Y yellow. The dispersed metallic particles can be given the desired color by any preferably method known in the art for the addition of such a color to such metallic particles, ranging from the simple physical adsorption of a dye by the colloidal particles, to the production of suitably colored organo-metallic complexes by part of the metallic particles. Although for clarity purposes, the three separate pixelated optical layered screen arrays are shown widely separated in FIG. 10, it is understood that in practice, the three layers are stacked in effective contact one on top of the other, to produce a thin screen with minimal parallax.

When no voltage is applied across a pixel 222 in the first layer, the color of the pixel is that of the colored metal, namely cyan. Application of an increasing voltage to the electrodes of that pixel causes the pixel to increasingly change from its non-transparent cyan color to become virtually fully transparent, if the switching layer has been correctly constructed, and the materials correctly selected, without too high or low a concentration of metal. If the concentration is too high, the pixel will not turn completely transparent when given its full driving voltage. If the concentration is too low, the pixel will not possess a sufficiently strong starting color to operate correctly as a subtractive filter. Likewise for the second layer, the pixels can be switched from fully magenta to virtually transparent, and likewise for the yellow, third layer. Since the layers are optically in series, the screen thus has the property that any composite pixel therein can be switched from virtually complete transparency to any combination of the cyan-magenta-yellow color combination. The screen is viewed by incident ambient light 224, being reflected from the back reflecting surface 220, and the whole assembly thus constitutes a reflective display, which emulates the subtractive color printing process.

Though this novel color display panel embodiment has been described using the above described optical switching device as its operative element, it is to be understood that it is operable also with any other type of pixelated display material which can be transformed from transparent to any other color by means of the voltage applied across the pixels.

According to another preferred embodiment of the present invention, the subtractive process display can also be implemented in a transmissive embodiment, using a white light source projected through the three serially disposed pixelated latched optical switches, each having one of the C, M and Y colors.

Reference is now made to FIG. 11, which illustrates schematically a touch screen display, constructed and operative according to a first preferred embodiment of the present invention. This embodiment can be utilized in the “select-an-icon” configuration, as will be apparent from a preferred mode of operation. In this preferred embodiment both the touch screen and the display screen are integrated into one device. The display screen shown in the preferred embodiment of FIG. 11 is liquid crystal based, but it is to be understood that the invention is equally operable with other types of suitable display elements.

The structure of the touch screen display illustrated in FIG. 11, comprises a display material 310 in contact with a planar switching layer 312, preferably of the type described in this application hereinabove. A suitably aligned polarizer 314 and analyzer 315 on either side of the liquid crystal/switch combination, aligned at 90° to each other according to one preferred embodiment, ensure that the light transmitted through the liquid crystal renders the image visible. The entire display is pixelated preferably by means of a layer of transparent electrical conductors 316 running in the x-axis direction, and a similar layer of conductors 318 running in the y-axis direction. The region of the display element/switch combination defined by the crossing points of any pair of such conductors constitutes a pixel of the display. The term crossing point is understood to mean the crossing point of the projection of one conductor onto the other, since the conductors, being spatially separated, do not physically cross each other. The application of pressure on a particular pixel having a closed switch, causes the switch to open. This opening can be utilized in a number of preferred ways, as will be described hereinbelow.

According to one preferred embodiment, when the screen has an image displayed, every pixel of the image that is functionally on is black, meaning that the local planar switch associated with that pixel is closed. In this state, according to one preferred method of use, a selection is performed by pressing on an icon that is displayed. The icon is made up of a large number of pixels, but a selected icon can be identified by first determining, by scanning the complete array of latching switch elements, whether any pixel in the display has been pressed, and then determining in which icon that pixel is located. Equivalently, it may be determined whether any of the switches associated with a given icon have changed their state. Since application of pressure opens the switch, there is a need to examine if any of the switches that are associated with a given icon were opened. Therefore, the current image must preferably be scanned line by line, and row by row, and changes of the impedance of any of the pixels must be verified. The row or column associated with that pixel then define the icon which was pressed.

As each pixel is in essence a sandwich of the “planar latched switch” material and the display material, whether it be liquid crystal or any other suitable display material, the touch-indicating circuitry is operative to calculate the per-pixel impedances of these two materials in series. The impedance per pixel of the display material and of the switching material are known, in both the “on” and “off” states, i.e. with the switch closed or open, respectively. In order to display images on the screen, a voltage is preferably applied across each element, and by dividing the voltage applied to a given pixel by the current running through that pixel, the series impedance of the pixel is obtained. From the level of this series impedance, the series impedance of the switching layer and hence its state, open or closed, may be determined. This then defines whether that pixel has been touched or not.

According to another preferred embodiment of the present invention, whereby the touch screen is operated in what is known as the “Draw on a black screen” configuration, the screen is initially turned fully black. According to this embodiment, writing is different from the usual writing mode, since white characters are written on a black background, compared with the usual black characters on a white background. Using the switching layer, any pixel is “turned on” when its associated switching layer pixel is closed, i.e. producing a black pixel. When any pixel in such a display configuration is pressed, the following events take place:
(i) As described in the first embodiment, scanning mode voltages are constantly applied to the matrix rows and columns, and the current per row and column are monitored continuously in order to determine the location of the pressure.
(ii) When a point on the screen is pressed, the switch associated with that point opens, and the display pixel switches to white, which is the color of its off state.
(iii) At the same time, the current through that pixel becomes low, such that the fact that the pixel has been turned off by the finger pressure is easily detectable by the electronic circuitry.

In both of the above-mentioned embodiments, both the touch screen and the display screen are integrated into one device. According to a further preferred embodiment of the present invention, the switch is operated independently of the display, as an external or additional overlay layer. This is the most generally used manner in which touch-screen panels are applied, as mentioned in the background section above.

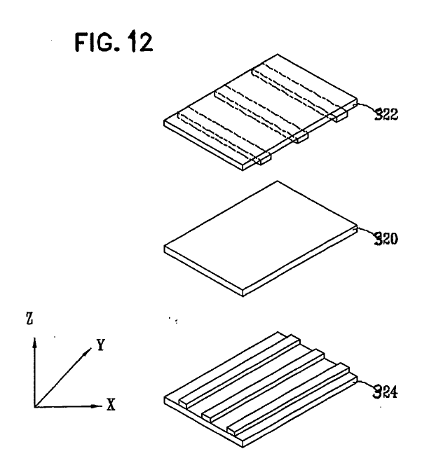

Reference is now made to FIG. 12, which is a schematic illustration of an independent touch panel layer, according to a preferred embodiment, for mounting on top of a display screen. The switching layer 320 is sandwiched between two substrates, preferably of a flexible film such as polyester or polyethylene. One substrate 322 has a patterned layer of transparent electrical conductors running in the x-axis direction, and the other 324, a similar patterned layer of conductors preferably running in the y-axis direction. The conductors are preferably made of Indium Tin Oxide, which is conductive and optically transparent. The crossing points of the patterned layers define the pixels of the switched layer.

This embodiment preferably operates in the following way. All of the pixels of the touch screen are initially closed. When the user presses the touch screen, the pixels beneath the touched region open. Electronic circuitry detects this by scanning row by row, as previously explained. According to one preferred embodiment, the electronic circuitry inputs only the location of the touch to the information processing device. According to a second preferred embodiment, the circuitry is arranged also to provide feedback to the display screen on which the touch panel is disposed, to indicate visually where the touch was effected.

When the touch-screen panel containing the switching material is external, as described above, the display screen is already protected by the standard display protection layer, and requires no additional protection. Furthermore, according to this embodiment, the writing can be performed in a “write on white mode” and not in the “write on black” mode described in FIG. 11, because the touch screen is not part of the display, and the display is therefore able to operate independently of the touch screen.

There are two complications in the implementation of the above-mentioned embodiments:

(i) The most common display material in use today is a liquid crystal. Liquid crystal materials are sensitive to pressure, and usually require the provision of a protective glass or plastic cover to prevent pressure on the material. However, the above-mentioned embodiments require the application of pressure on the switch in order to operate the touch screen.

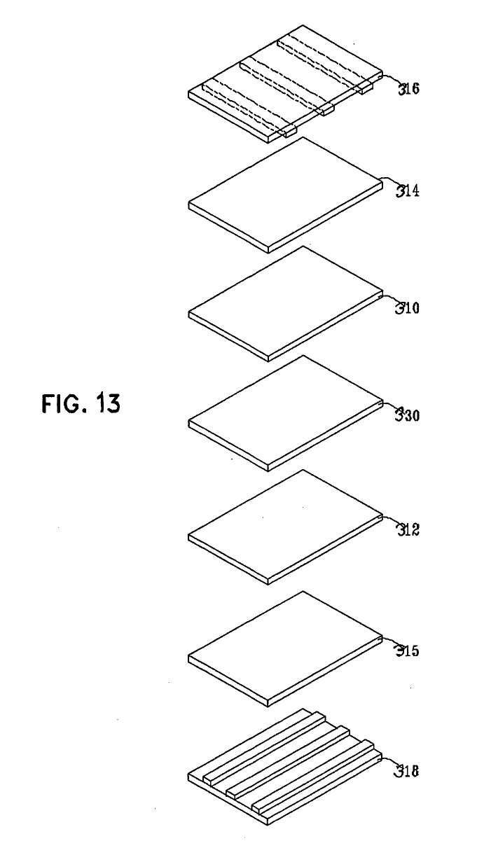

A preferred method of overcoming this problem is illustrated in FIG. 13. FIG. 13 shows a touch screen display similar to that shown in FIG. 11, and with the same part nomenclature, but with the addition of a thin solid layer 330, of a material conductive only in the z direction, and not in the x or y directions, disposed between the liquid crystal and switch layers. This thin transparent layer has a selected level of stiffness, such that it protects the liquid crystal material from pressure which would alter its transmissive properties, and yet passes the voltages through to the liquid crystal material as required, if a given pixel's switch is closed.

If a solid material which is not sensitive to pressure, is used as the display material, the pressure problem is obviated. Alternatively and preferably, the switch layer could be placed under the displaying medium, thus isolating it from the full effect of the pressure. This has the added advantage that it eleiminates any reduction in display clarity or transparency.

(ii) The current in the rows and columns needs to be virtually continuously monitored to determine when and where a touch has been effected. This monitoring determines either whether the current is under or is over a certain level. This is the case since the current, when a voltage is applied across the pixel, can assume one of two values:
(a) I=V/(Z_{Displaying medium}+Z_{Switching device, ON}); or
(b) I=V/(Z_{Displaying medium}+Z_{Switching device, OFF});
where Z denotes the impedance, Z_{Displaying medium} denoting the impedance of the displaying medium itself, and Z_{Switching device, ON} and Z_{Switching device, OFF} respectively denoting the ON and OFF impedances of the switch. For the embodiments shown in FIG. 12, where only a touch panel is used, the value of Z_{Displaying medium} is zero, and the impedance measured is simply that of the switching device only.

It will be appreciated by persons skilled in the art that the present invention is not limited by what has been particularly shown and described hereinabove. Rather the scope of the present invention includes both combinations and subcombinations of various features described hereinabove as well as variations and modifications thereto which would occur to a person of skill in the art upon reading the above description and which are not in the prior art.

We claim:

1. A switching device comprising:
a pair of electrodes for applying a switching voltage; and
a switching material disposed between said electrodes, said switching material comprising a mixture of a conductive material dispersed in an insulating material.

2. A switching device according to claim 1 and wherein said switching material is such that said switching device closes only when said voltage is greater than a predefined threshold voltage.

3. A switching device according to claim 1 and wherein said switching material is such that said switching device is bi-stable.

4. A switching device according to claim 1 and wherein said switching material is such that said switching device is latched.

5. A switching device according to claim 1 and wherein said insulating material comprises at least one of an epoxy resin and a polymer.

6. A switching device according to claim 5 and wherein said epoxy resin is uncured.

7. A switching device according to claim 1 and wherein said conductive material is a metal.

8. A switching device according to claim 7 and wherein said metal is selected from a group consisting of silver, iron, gold, copper, aluminum and zinc.

9. A switching device according to claim 1 and wherein the concentration of said conductive material is in the range of 0.005% to 20%.

10. A switching device according to claim 1 and wherein said insulating material is an organic solvent and said conductive material is a metallic impurity in said solvent.

11. A switching device according to claim 1 and also comprising a piezoelectric component operative to open said switch when closed.

12. A switching device according to claim 11 and wherein said piezoelectric component is dispersed in said switching material.

13. A switching device according to claim 1 and wherein said switching material also comprises an elastomeric component.

14. A switching device according to claim 1, and wherein said electrodes comprise a transparent conductive layer coated on a thin insulating sheet.

15. A switching device according to claim 14, and wherein said transparent conductive layer is comprised of indium tin oxide.

16. A switching device according to claim 1 and wherein said device is an information storage device.

17. A latched switching device comprising:
a pair of electrodes for applying a switching voltage; and
a polymeric switching material disposed between said electrodes, said material switching between latched electrical conductive states as a function of said switching voltage;
wherein said switching device maintains its latched state after removal of said switching voltage, by application of a sustaining voltage substantially less than said switching voltage.

18. A latched switching device according to claim 17 and wherein said polymeric material is an epoxy resin.

19. A latched switching device according to claim 17 and wherein said polymeric material is essentially optically transparent.

20. A latched switching device according to claim 17 and wherein said polymeric material is deposited by a spin-coating process essentially at room temperature.

21. A switching device according to claim 17, and wherein said device is an information storage device.

22. A latched switching device comprising:
a pair of electrodes for applying a switching voltage; and
a polymeric switching material disposed between said electrodes, said material switching between latched electrical states as a function of said switching voltage,
wherein said switching device maintains its latched state after removal of said switching voltage for a time substantially less than one second, before reverting to its unlatched state.

23. A latched switching device according to claim 22 and wherein said polymeric material is an epoxy resin.

24. A latched switching device according to claim 22 and wherein said polymeric material is essentially optically transparent.

25. A latched switching device according to claim 22 and wherein said polymeric material is deposited by a spin-coating process essentially at room temperature.

26. A switching device according to claim 22, and wherein said device is an information storage memory.

27. A latched switching device comprising:
a pair of electrodes for applying a switching voltage; and
an epoxy switching material disposed between said electrodes, said material switching between latched electrical conduction states as a function of said switching voltage;
wherein said switching device maintains its latched state after removal of said switching voltage for a time substantially longer than ten seconds before reverting to its unlatched state.

28. A switching device according to claim 27 and wherein said epoxy material is deposited by a spin-coating process essentially at room temperature.

29. A switching device according to claim 27, and wherein said device is an information storage device.

30. An optical switching device comprising:
a pair of generally transparent electrodes for applying a voltage; and
a layer of generally transparent switching material disposed between said electrodes, said switching material comprising a mixture of a conductive material dispersed in an insulating material,
wherein said switching device has an optical transmission which is a function of said applied voltage.

31. An optical switching device according to claim 30 and wherein said switching material is such that said switching device is bi-stable.

32. An optical switching device according to claim 30 and wherein said switching material is such that said switching device is latched.

33. An optical switching device according to claim 30 and wherein said insulating material comprises at least one of an epoxy resin and a polymer.

34. An optical switching device according to claim 33 and wherein said epoxy resin is uncured.

35. An optical switching device according to claim 30 and wherein said conductive material is a metal.

36. An planar optical switching device according to claim 35 and wherein said metal is selected from a group consisting of silver, iron, gold, copper and zinc.

37. An optical switching device according to claim 30 and wherein the concentration of said conductive material is in the range of 0.005% to 20%.

38. An switching device according to claim 30 and wherein said insulating material is an organic solvent and said conductive material is a metallic impurity in said solvent.

39. An optical switching device according to claim 30 and also comprising a piezoelectric component operative to open said switching device when closed.

40. An optical switching device according to claim 39 and wherein said piezoelectric component is dispersed in said switching material.

41. An optical switching device according to claim 30 and wherein said switching material also comprises an elastomeric component.

42. An optical switching device according to claim 30, and wherein said electrodes comprise a transparent conductive layer coated on a thin insulating transparent sheet.

43. An optical switching device according to claim 42, and wherein said transparent conductive layer is comprised of indium tin oxide.

44. An optical switching device according to claim 30, and wherein said device is any one of a planar and a curved device.

45. A switching material comprising:
an insulating base material; and
a conductive material dispersed through said insulating base material;
wherein said switching material changes at least one of its electrical conductivity and its optical transmissivity in a latched manner when subjected to an applied electric field.

46. A switching material according to claim 45, and wherein said insulating base material is essentially transparent.

47. A display comprising:
a pixelated imaging layer, the pixels of said layer being generally separately addressable by applied signals; and
a latched switching layer in serial electrical contact with said imaging layer, at least one area of said latched switching layer being switchable to a closed electrical state as a result of the signal applied to the pixel proximate to said at least one area.

48. A display according to claim 47 and wherein said signal is applied to the series combination of said pixel and said at least one area of said latched switching layer proximate to said pixel and in serial electrical contact therewith.

49. A display according to claim 47, and wherein said imaging layer is a liquid crystal device.

50. A display according to claim 47, and wherein said applied signals are provided by sets of orthogonal conductors disposed on either side of said imaging layer and said latched switching layer.

51. A display according to claim 47, and wherein said pixels of said latched switching layer are latched to said closed state by said applied signals, and maintain their electrical state after said applied signals have been removed.

52. A display according to claim 47, and wherein said latched switching layer comprises a layer of switching material.

53. A display according to claim 52, and wherein said switching material comprises a mixture of a conductive material dispersed in an insulating material.

54. A display according to claim 52, and wherein said switching material comprises a polymeric material.

55. A display according to claim 47, and wherein said display is electrically refreshed at a predetermined rate, said latched switching layer being such that a switched area of said layer remains latched closed after removal of said applied signal for a time shorter than said refresh rate of said display, such that said pixels of said imaging layer may be rewritten without the application of an erase signal.

56. A display according to claim 55, and wherein said latched switching layer is such that a switched area of said layer remains latched closed after removal of said applied signal, provided that a sustaining voltage, smaller than said signal, is applied to said area.

57. A display according to claim 55 and wherein said time is less than 5 milliseconds.

58. A display according to claim 47 and wherein said latched switching layer is selected from a group consisting of organic switches, glassy-type bi-stable switches, semiconductor array bi-stable switches, low-band gap conjugated polymer switches, amorphous chalcogenide semiconductors, ZnSe—Ge heterostructures, amorphous silicon conducting polymers, a variety of binary and ternary oxides, ferroelectric heterostructures, MIM structures with oxides such as (Ba,Sr)TiO₃, SrZrO₃, SrTiO₃, Ca₂Nb₂O₇ and Ta₂O₅ doped with up to 0.2% of Cr or V as the insulator layer, and molecular switches.

59. A display according to claim 47, and wherein the impedance of said latched switching layer is a variable function of said applied signals, such that said pixels of said imaging layer can be switched to various gray levels.

60. A display according to claim 47, and wherein said pixels are any one of real pixels and virtual pixels formed at the intersections of said orthogonal conductors.

61. A method of displaying an image in a display device, comprising the steps of:
providing an imaging layer divided into pixels, each of said pixels being separately addressable by an applied switching voltage;
providing a latched switching layer in serial electrical contact with said imaging layer;
applying a switching voltage to a pixel of said imaging layer in serial electrical contact with said latched switching layer, said switching voltage being sufficient to close the switch in an area of said latched switching layer in contact with said pixel;
applying further switching voltages sequentially to other pixels of said imaging layer in serial electrical contact with said latched switching layer according to the desired image; and
subsequently applying an activating voltage simultaneously to a plurality of pixels of said imaging layer in serial electrical contact with said latched switching layer, said activating voltage being sufficient to switch said pixels of said imaging layer to show said desired image.

62. The method of claim 61, and also comprising the subsequent step of applying an erasing voltage to those pixels of said imaging layer in serial electrical contact with said latched switching layer, where it is desired that the image be erased.

63. The method of claim 61, and wherein said switching voltages are applied by means of orthogonal conductors located on either side of said imaging layer and said latched switching layer.

64. The method of claim 61, and wherein said switching voltages are any one of DC voltages and AC voltages.

65. The method of claim 61, and wherein said pixels are any one of real pixels and virtual pixels formed at the intersections of said orthogonal conductors.

66. A method of changing the operative condition of at least one element of a system, said system comprising a plurality of said elements, and said system being operable by alternating said conditions of said elements, comprising the steps of:
providing a system comprising a plurality of said elements;
disposing a latched switching layer in electrical contact with at least one of said plurality of elements, the operative condition of said at least one of said plurality of elements being alternated by the application of a signal to the series combination of said at least one element and said latched switching layer proximate to said at least one element and in serial electrical contact therewith.

67. The method of claim 66 and wherein said application of said signal is operative also to close said latched switching layer proximate to said element.

68. The method of claim 66 and wherein the condition of said at least one element is alternated without the need for an additional control signal applied by means of an additional control lead.

69. The method of claim 66, wherein said system is at least one of a pixelated display, a touch screen and a keyboard.

70. A system comprising a plurality of elements, at least one of said elements having at least two alternate operative conditions, said system being operable by alternating said conditions of said elements, and further comprising a latched switching layer disposed in electrical contact with at least one of said plurality of elements, the operative condition of said at least one of said elements being alternated by the application of a signal to the series combination of said at least one element and said latched switching layer proximate to said at least one element and in serial electrical contact therewith.

71. The system of claim 70, and wherein the condition of said at least one element is alternated without the need for an additional control signal applied by means of an additional control lead.

72. The system of claim 70, wherein said system is at least one of a pixelated display, a touch screen and a keyboard.

73. A color display, comprising:
three pixelated filters of different colors disposed one on top of each other, each of the pixels in each of said filters having a color density electrically variable from its maximum color density to essential transparency, wherein the colors of said three filters constitute a subtractive color set.

74. A color display according to claim 73, and wherein said subtractive color set comprises the colors cyan, magenta and yellow.

75. A color display according to claim 73 and also comprising a reflective surface disposed behind said three pixelated filters opposite to the side from which said display is adapted to be viewed.

76. A color display according to claim 73 and wherein each of said filters is effectively pixelated by means of generally transparent arrays of electrodes defining pixelated areas on said filters.

77. A color display according to claim 73 and wherein each of said filters is physically pixelated.

78. A color display according to claim 73, and wherein each of said pixelated filters comprises:
a pair of generally transparent arrays of electrodes for applying voltages, said arrays of electrodes defining pixelated areas on said filters; and
a layer of material disposed between said electrodes, said material comprising a mixture of a conductive material having the color of said filter in which it is installed, dispersed in a generally transparent insulating material, such that the optical color density of said pixelated areas of said filters is varied by said applied voltages.

79. A color display according to claim 78, and wherein said conductive material is a finely divided metal.

80. A color display according to claim 79, and wherein said metal is selected from a group consisting of silver, iron, gold, copper and zinc.

81. A color display according to claim 78, and wherein said insulating material comprises at least one of an epoxy resin and a polymer.

82. A color display according to claim 78, and wherein said conductive material is colored by the association thereto of a dye.

83. A color display according to claim 78, and wherein said conductive material is colored by means of an organo-metallic complex.

84. A color display according to claim 78, and wherein said pixelated electrodes comprise indium tin oxide.

85. A method of generating colors in a display panel, comprising the steps of:
providing a set of three pixelated filters of colors constituting a subtractive color set, the transmission of said filters being electrically variable from maximum color density to essential transparency;
disposing said filters one on top of the other, such that at least one set of corresponding pixels of each of said filters are superposed;
applying voltages to said at least one set of superposed pixels, one in each of said filters; and
adjusting the color densities of said at least one set of superposed pixels by varying said voltages, such that light passing through said set of superposed pixels acquires a predetermined color by means of a subtractive color process.

86. The method of claim 85, and wherein each of said filters is effectively pixelated by means of generally transparent pixelated arrays of electrodes defining pixelated areas on said filters.

87. The method of claim 85, and wherein each of said filters is physically pixelated.

88. The method of claim 85 and wherein said display panel has a resolution approximately three times better than an additive display having corresponding features.

89. The method of claim 85 and wherein said display panel has an optical efficiency approximately three times better than an additive display having corresponding features.

90. A method of improving the performance of a display panel comprising three sets of pixelated filters of different colors, comprising the steps of:
selecting said colors to be a subtractive color set;
disposing said filters one on top of the other, such that at least one set of corresponding pixels of each of said filters are superposed; and
activating said set of superposed pixels in a subtractive mode.

91. A method according to claim 90 and wherein said performance is at least one of the resolution of said display panel and the optical efficiency of said display panel.

92. A touch panel comprising:
a first planar electrode having a first array of conductors;
a second planar electrode having a second array of conductors oriented at an angle to said first array of conductors; and
a pressure-sensitive, planar latching switching layer disposed between said electrodes.

93. A touch panel according to claim 92, wherein the crossing points of said first array of conductors and said second array of conductors define at their crossing points a set of pixels for said touch panel.

94. A touch panel according to claim 92, wherein said angle is such that said first and second arrays of conductors are essentially orthogonal.

95. A touch panel according to claim 92, wherein said switching layer is such that the action of pressure on an area of said layer is at least one of to electrically open closed switch regions within said area and to electrically close open switch regions within said area.

96. A touch panel according to claim 95, wherein the position in said panel at which said pressure is applied is determined by measurement of the impedance between at least one of said conductors of said first array and at least one of said conductors of said second array.

97. A touch panel according to claim 95, wherein the position in said panel at which said pressure is applied is determined by sequential electronic scanning of said first array of conductors and said second array of conductors to detect impedance changes between any pair of conductors, one from said first array of conductors and one from said second array of conductors.

98. A touch panel according to claim 92, and wherein said touch panel is overlaid on a flat panel display, such that said touch panel is operative with said display.

99. A touch screen comprising:
a first planar electrode having a first array of conductors;
a second planar electrode having a second array of conductors oriented at an angle to said first array of conductors;
a pressure-sensitive, planar latching switching layer disposed between said electrodes; and
a planar display layer disposed between said electrodes and in electrical contact with said pressure-sensitive, planar latching switching layer.

100. A touch screen according to claim 99, wherein said angle is such that said first and second arrays of conductors are essentially orthogonal.

101. A touch screen according to claim 99, wherein said switching layer is such that a voltage applied between at least one of said conductors of said first array and at least one of said conductors of said second array is operative to close the switch area of said planar latching switching layer between said conductors to which said voltage is applied, and to activate a corresponding area of said planar display layer.

102. A touch screen according to claim 101, wherein said areas between said conductors to which voltage is applied, defines pixels of said touch screen.

103. A touch screen according to claim 99, wherein said switching layer is such that the action of pressure on an area of said layer is at least one of to electrically open closed switch regions within said area and to electrically close open switch regions within said area.

104. A touch screen according to claim 103, wherein the position in said panel at which said pressure is applied is determined by measurement of the impedance between at least one of said conductors of said first array and at least one of said conductors of said second array.

105. A touch screen according to claim 103, wherein the position in said panel at which said pressure is applied is determined by sequential electronic scanning of said first array of conductors and said second array of conductors to detect impedance changes between any pair of conductors, one from said first array of conductors and one from said second array of conductors.

106. A touch screen according to claim 103, wherein said switching layer is such that the action of pressure to open said closed switch regions within said area is also operative to change the optical state of the display layer associated with said switch regions.

107. A touch screen according to claim 103, wherein said switching layer is such that the action of pressure to close said open switch regions within said area is also operative to change the optical state of the display layer associated with said switch regions.

108. A touch screen according to claim 99 and wherein said planar display layer is a liquid crystal layer.
